(19) United States
(12) Patent Application Publication
(10) Pub. No.: US 2025/0372471 A1
(43) Pub. Date: Dec. 4, 2025

(54) SEMICONDUCTOR PACKAGES

(71) Applicant: Samsung Electronics Co., Ltd., Suwon-si (KR)

(72) Inventor: Gunho Chang, Suwon-si (KR)

(21) Appl. No.: 19/023,833

(22) Filed: Jan. 16, 2025

(30) Foreign Application Priority Data
May 29, 2024 (KR) 10-2024-0070351

(51) Int. Cl. H01L 23/31; H01L 25/07

(52) U.S. Cl. CPC H01L 23/3178; H01L 23/3192; H01L 25/074; H01L 2225/06513; H01L 2225/06517; H01L 2225/06541

(57) ABSTRACT

A semiconductor package includes a first semiconductor chip having a chip region and a dummy region surrounding the chip region in a plan view, a second semiconductor chip on an upper surface of the chip region of the first semiconductor chip, and a molding layer configured to cover the second semiconductor chip on the first semiconductor chip, wherein the first semiconductor chip has a recessed portion in an outer wall of the first semiconductor chip and an upper surface of the dummy region of the first semiconductor chip, and surface roughness of an inner surface of the recessed portion of the first semiconductor chip is greater than surface roughness of an outer wall of the molding layer.

### CROSS-REFERENCE TO RELATED APPLICATION

This application is based on and claims priority under 35 U.S.C. § 119 to Korean Patent Application No. 10-2024-0070351, filed on May 29, 2024, in the Korean Intellectual Property Office, the disclosure of which is incorporated by reference herein in its entirety.

### FIELD OF THE INVENTION

The inventive concept relates to a semiconductor package, and more particularly, to a semiconductor package including stacked semiconductor chips.

### BACKGROUND OF THE INVENTION

Semiconductor packages are provided by fabricating integrated circuit chips into forms suitable for use in electronic products. Generally, in the semiconductor packages, semiconductor chips are mounted on a printed circuit board, and bonding wires or bumps establish electrical connections therebetween. As the electronics industry develops, the semiconductor packages may be required to exhibit high-capacity characteristics. In addition, as electronic products become smaller, demands for compact semiconductor packages are increasing.

### SUMMARY

The inventive concept provides a semiconductor package having improved reliability.

The inventive concept also provides a method of manufacturing a semiconductor package having improved yield and the semiconductor package manufactured thereby.

According to an aspect of the inventive concept, there is provided a semiconductor package including a first semiconductor chip having a chip region and a dummy region surrounding the chip region in a plan view, a second semiconductor chip on an upper surface of the chip region of the first semiconductor chip, and a molding layer configured to cover the second semiconductor chip on the first semiconductor chip, wherein the first semiconductor chip has a recessed portion in an outer wall of the first semiconductor chip and an upper surface of the dummy region of the first semiconductor chip, and a surface roughness of an inner surface of the recessed portion of the first semiconductor chip is greater than a surface roughness of an outer wall of the molding layer.

According to another aspect of the inventive concept, there is provided a semiconductor package including a first semiconductor chip, a second semiconductor chip on an upper surface of the first semiconductor chip, and a molding layer configured to cover a sidewall of the second semiconductor chip on the upper surface of the first semiconductor chip, wherein the first semiconductor chip includes a semiconductor substrate, and an upper insulating layer provided on the semiconductor substrate and having a recessed portion, and wherein the recessed portion of the upper insulating layer is provided in an outer wall and an upper surface of the upper insulating layer, and a surface roughness of an inner surface of the recessed portion of the upper insulating layer is greater than a surface roughness of an outer wall of the semiconductor substrate.

According to another aspect of the inventive concept, there is provided a semiconductor package including a first semiconductor chip including a first semiconductor substrate, a first lower insulating layer on a lower surface of the first semiconductor substrate, a first lower pad on a lower surface of the first lower insulating layer, a first through-via within the first semiconductor substrate, a first upper pad electrically connected to the first through-via, and a first upper insulating layer on an upper surface of the first semiconductor substrate, a plurality of second semiconductor chips stacked on an upper surface of the first semiconductor chip, each of the plurality of second semiconductor chips including a second semiconductor substrate, a second lower insulating layer, a second lower pad, a second through-via, a second upper insulating layer, and a second upper pad, a molding layer disposed on the upper surface of the first semiconductor chip and configured to cover sidewalls of the plurality of second semiconductor chips, and a lower bump provided on a lower surface of the first semiconductor chip and electrically connected to the first lower pad, wherein the first semiconductor chip has a recessed portion in an outer wall of the first semiconductor chip and the upper surface of the first semiconductor chip, a surface roughness of an inner surface of the recessed portion of the first semiconductor chip is greater than a surface roughness of an outer wall of the molding layer and a surface roughness of an outer wall of the first semiconductor substrate, and the molding layer extends into the recessed portion of the first semiconductor chip and covers the inner surface of the recessed portion of the first semiconductor chip.

### BRIEF DESCRIPTION OF THE DRAWINGS

Embodiments will be more clearly understood from the following detailed description taken in conjunction with the accompanying drawings in which:

FIG. 1A is a plan view illustrating a semiconductor package according to some embodiments;

FIG. 1B is a cross-section of the semiconductor package taken along line I-I′ of FIG. 1A;

FIG. 1C is an enlarged view of region II of FIG. 1B;

FIG. 1D is an enlarged view of region III of FIG. 1B;

FIG. 1E is a diagram illustrating an alternative recessed portion according to some embodiments;

FIG. 1F is a diagram illustrating an alternative recessed portion according to some embodiments;

FIG. 1G is a diagram illustrating an alternative recessed portion according to some embodiments;

FIG. 1H is a diagram illustrating an alternative recessed portion according to some embodiments;

FIG. 2A is a cross-sectional view illustrating a semiconductor package according to further embodiments;

FIG. 2B is an enlarged view of region II of FIG. 2A;

FIG. 3 is a cross-sectional view illustrating a semiconductor package according to further embodiments;

FIG. 4 is a cross-sectional view illustrating a semiconductor package according to further embodiments;

FIG. 5A is a cross-sectional view illustrating a semiconductor wafer according to some embodiments;

FIG. 5B is an enlarged view of region IV of FIG. 5A;

FIGS. 6A to 6I are diagrams illustrating a manufacturing process of a semiconductor package, according to some embodiments;

FIGS. 7A to 7C are diagrams illustrating a manufacturing process of a semiconductor package, according to further embodiments; and

FIG. 8 is a cross-sectional view illustrating a semiconductor package according to some embodiments.

### DETAILED DESCRIPTION

The above and other aspects and features of the semiconductor package and the methods of manufacturing the same in accordance with example embodiments will become readily understood from the detailed descriptions that follow, with reference to the accompanying drawings.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

Components or layers described with reference to “overlap” in a particular direction are at least partially obstructed by one another when viewed along a line extending in the particular direction or in a plane perpendicular to the particular direction. As used herein, “an element A overlapping an element B in a direction C” (or similar language) means that there is at least one line that extends in the direction C that intersects both the element A and the element B. For example, the element B may be a layer that is stacked or superimposed over (i.e., on top of) the element A, in which case the layer B may be described as overlapping the element A in a vertical direction. However, it will be appreciated that the direction C is not limited to the vertical direction and may be, for example, a horizontal direction or any direction between vertical and horizontal.

The term “exposed” may be used to describe relationships between elements and/or certain intermediate processes in fabricating a completed semiconductor device but may not necessarily require exposure of the particular region, layer, structure or other element in the context of the completed device. An “element A is exposed by an element B” means that at least a portion of the element A is not covered by the element B. However, the thus exposed portion of the element A may be covered by a third element.

For the purpose of explanation, certain dimensions of components are described herein as a component's “width” and the component's “length”. Unless otherwise specified, the use of these terms is not intended to mean that the width of the component is necessarily less than its length.

In this specification, the same reference numerals may refer to the same elements throughout. A semiconductor package and a manufacturing method thereof according to embodiments are described.

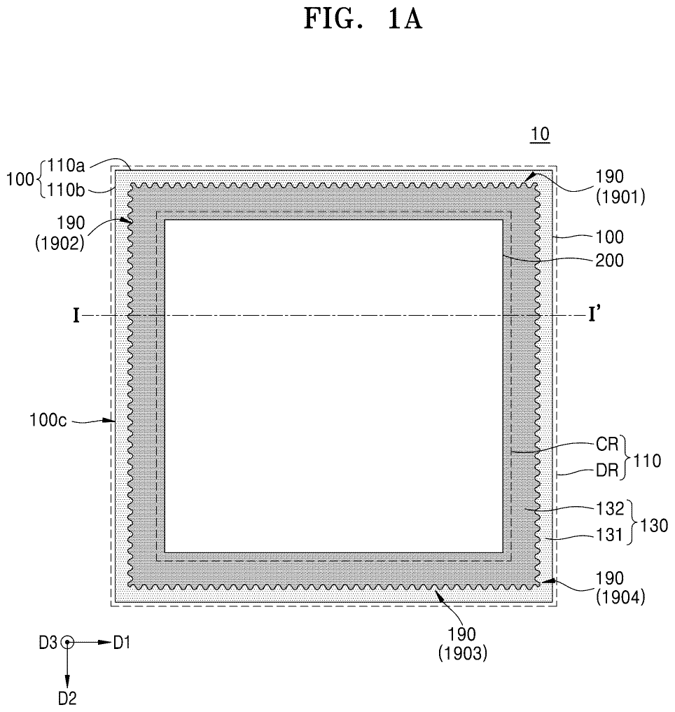

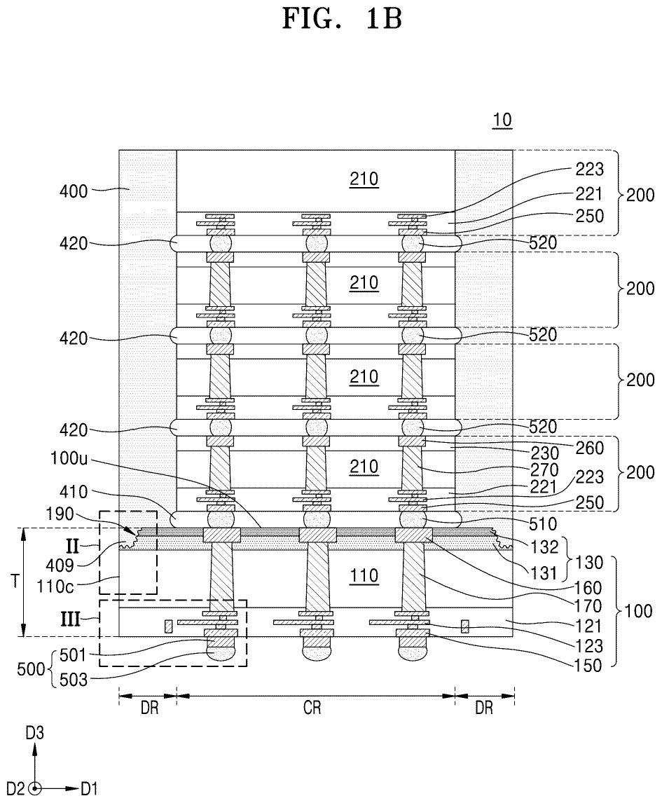

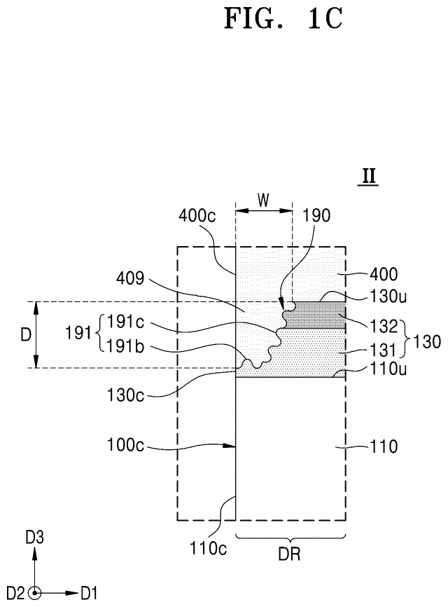

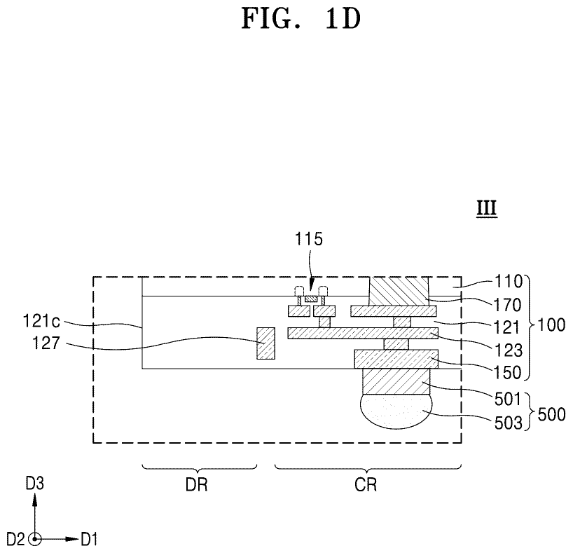

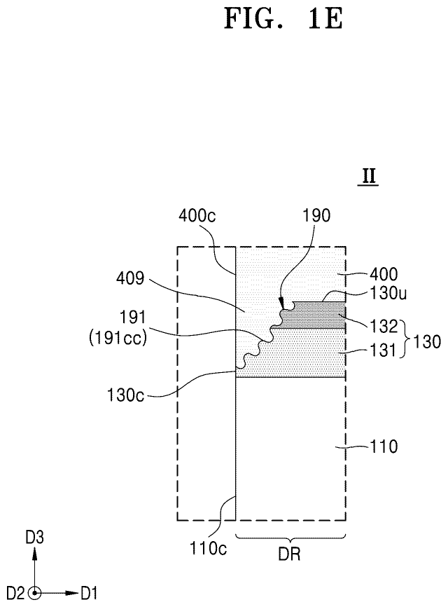

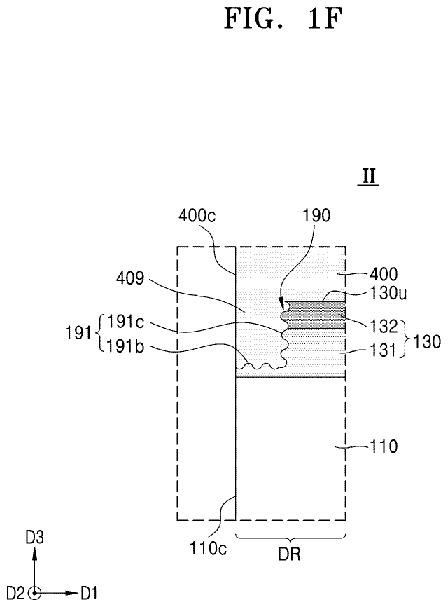

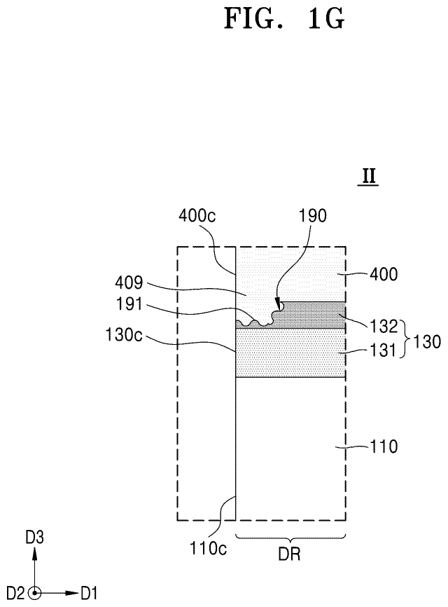

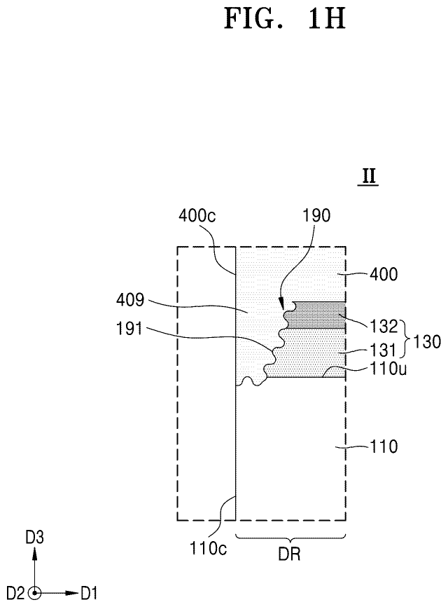

FIG. 1A is a plan view illustrating a semiconductor package 10 according to some embodiments. FIG. 1B is a cross-section of the semiconductor package 10 taken along line I-I′ of FIG. 1A. FIG. 1C is an enlarged view of region II of FIG. 1B. FIG. 1D is an enlarged view of region III of FIG. 1B.

Referring to FIGS. 1A to 1D, the semiconductor package 10 may include a memory package, such as a high bandwidth memory (HBM) package. The semiconductor package 10 may include a chip stack package. The semiconductor package 10 may include a first semiconductor chip 100, second semiconductor chips 200, a molding layer 400, and a lower bump 500.

The first semiconductor chip 100 may be a lower semiconductor chip. The first semiconductor chip 100 may include a logic chip or a buffer chip. The first semiconductor chip 100 may include a first semiconductor substrate 110, a first lower pad 150, a first lower insulating layer 121, a first wiring pattern 123, a first through-via 170, a first upper insulating layer 130, and a first upper pad 160. A first direction D1 may be parallel to the lower surface of the first semiconductor substrate 110. A second direction D2 may be parallel to the lower surface of the first semiconductor substrate 110. The second direction D2 may be parallel to the lower surface of the first semiconductor substrate 110 and intersect with the first direction D1. For example, the second direction D2 may be perpendicular to the first direction D1. For example, a third direction D3 may be perpendicular to the lower surface of the first semiconductor substrate 110. The third direction D3 may represent a vertical direction.

A thickness T of the first semiconductor chip 100 may be about 30 μm to about 80 μm. Since the thickness T of the first semiconductor chip 100 is 80 μm or less, the size of the semiconductor package 10 may be reduced. Since the thickness T of the first semiconductor chip 100 is 30 μm or more, damage to the first semiconductor chip 100 may be prevented during the manufacturing process of the semiconductor package 10. The thickness T of the first semiconductor chip 100 may correspond to the distance between the lower surface and the upper surface of the first semiconductor chip 100.

A plurality of second semiconductor chips 200 may be provided on the first semiconductor chip 100. The second semiconductor chips 200 may be vertically stacked on the upper surface 100u of the first semiconductor chip 100. Unless otherwise specified herein, “vertical” may represent parallel to the third direction D3. The second semiconductor chips 200 may be upper semiconductor chips. The second semiconductor chips 200 may be identical to each other. Each of the second semiconductor chips 200 may include a memory chip, such as a dynamic random-access memory (DRAM) chip. For example, each of the second semiconductor chips 200 may include an HBM chip. The second semiconductor chips 200 may have the same storage capacity. The second semiconductor chips 200 may have the same size. For example, the second semiconductor chips 200 may have substantially the same width. The sidewalls of the second semiconductor chips 200 may be vertically aligned with each other. However, the thickness of a second semiconductor chip 200 located at the top (hereinafter, referred to as an uppermost second semiconductor chip 200) may be greater than the thicknesses of the remaining second semiconductor chips 200. The remaining second semiconductor chips 200 may have substantially the same thickness. The width of a component may be measured in the first direction D1. The thickness of a component may be measured in the third direction D3. The expression, in which the widths, thicknesses, sizes, levels, and widths of certain components are equal to each other, may indicate that the range of errors that may occur during the process is the same. The second semiconductor chips 200 may include different types of semiconductor chips from the first semiconductor chip 100. The width of the first semiconductor chip 100 may be greater than the width of each of the second semiconductor chips 200.

The number of second semiconductor chips 200 is not limited to that shown in FIG. 1B and may be variously modified. For example, the semiconductor package 10 may include a single second semiconductor chip 200 or at least four second semiconductor chips 200. For example, the semiconductor package 10 may include eight second semiconductor chips 200, twelve second semiconductor chips 200, or sixteen second semiconductor chips 200.

Hereinafter, components of the first semiconductor chip 100 are described.

The first semiconductor substrate 110 may represent a first substrate. The first semiconductor substrate 110 may have an element or chip region CR and a dummy region DR in a plan view. The chip region CR of the first semiconductor substrate 110 may correspond to a center region of the first semiconductor substrate 110. The dummy region DR of the first semiconductor substrate 110 may correspond to an edge region of the first semiconductor substrate 110. The dummy region DR of the first semiconductor substrate 110 may surround the chip region CR in a plan view. For example, the dummy region DR of the first semiconductor substrate 110 may be provided between the chip region CR and a side wall or outer wall 110c of the first semiconductor substrate 110. For example, the first semiconductor substrate 110 may include a semiconductor material, such as silicon, germanium, and silicon-germanium. The first semiconductor substrate 110 may include a crystalline semiconductor material.

The first semiconductor chip 100 may include first integrated circuits 115, as shown in FIG. 1D. The first integrated circuits 115 may be arranged on the lower surface of the chip region CR of the first semiconductor substrate 110. The lower surface of the first semiconductor substrate 110 may correspond to a frontside surface. The first integrated circuits 115 may not be provided on the dummy region DR of the first semiconductor substrate 110. The first integrated circuits 115 may include transistors. The first integrated circuits 115 may include logic circuits.

The first lower insulating layer 121 is provided on the lower surface of the first semiconductor substrate 110 and may cover the first integrated circuits 115. The first lower insulating layer 121 may include a silicon-based insulating material. The silicon-based insulating material may include, for example, silicon oxide, silicon nitride, silicon oxynitride, and/or silicon carbide oxynitride. The first lower insulating layer 121 may include a plurality of stacked layers.

The first wiring pattern 123 may be provided within the first lower insulating layer 121. The first wiring pattern 123 may be electrically connected to at least one of the first integrated circuits 115 and the first through-via 170. The expression, in which a component is electrically connected to a semiconductor chip, may indicate that the component is electrically connected to at least one of a through-via and integrated circuits of the semiconductor chip. As used herein, the expression, in which components are electrically connected/linked to each other, involves direct connection/linkage or indirect connection/linkage via another conductive component.

The first lower pad 150 may be disposed on the lower surface of the first semiconductor chip 100. For example, the first lower pad 150 may be disposed on the lower surface of the first lower insulating layer 121. The first lower pad 150 may be electrically connected to the first integrated circuits 115 and the first through-via 170 via the first wiring pattern 123. The first lower pad 150 may include, for example, aluminum or copper. The lower surface of the first semiconductor chip 100 may include the lower surface of the first lower pad 150 and the lower surface of the first lower insulating layer 121.

The lower bump 500 may be disposed on the lower surface of the first semiconductor chip 100. For example, the lower bump 500 may be disposed on the lower surface of the first lower pad 150 and electrically connected to the first lower pad 150. Accordingly, the lower bump 500 may be electrically connected to the first semiconductor chip 100 and the second semiconductor chips 200 via the first lower pad 150. The lower bump 500 may include a conductive pillar 501 and a solder ball 503. The conductive pillar 501 may be provided between the first lower pad 150 and the solder ball 503 and electrically connected to the first lower pad 150 and the solder ball 503. The conductive pillar 501 may include different materials from the first lower pad 150 and the solder ball 503. For example, the conductive pillar 501 may include copper and/or a copper alloy. The solder ball 503 may include a solder material. The solder material may include tin (Sn), silver (Ag), zinc (Zn), and/or an alloy thereof.

The first semiconductor chip 100 may further include a guide ring 127. The guide ring 127 may be provided within the first lower insulating layer 121. The guide ring 127 may have a closed loop shape in a plan view. The guide ring 127 may be provided between the dummy region DR of the first semiconductor substrate 110 and the first wiring pattern 123 in a plan view. The guide ring 127 may protect the first wiring pattern 123 or the first integrated circuits 115 from external contamination or external stress. The guide ring 127 may include a metal material, but the embodiment is not limited thereto.

The first through-via 170 may be provided within the first semiconductor substrate 110 and pass through the first semiconductor substrate 110. The first through-via 170 may further pass through at least a portion of the first lower insulating layer 121. The first through-via 170 may be electrically connected to the first wiring pattern 123. The first through-via 170 may be electrically connected to the first lower pad 150 and/or the first integrated circuits 115 via the first wiring pattern 123. For example, the first through-via 170 may include metals, such as copper (Cu), tungsten (W), titanium (Ti), titanium nitride (TiN), tantalum (Ta), and tantalum nitride (TaN).

As shown in FIG. 1B, the first upper insulating layer 130 may be disposed on the upper surface 110u of the first semiconductor substrate 110. The upper surface 110u of the first semiconductor substrate 110 may be opposite to the lower surface thereof. The upper surface of the first semiconductor substrate 110 may correspond to a backside surface. The first through-via 170 may be further provided within the first upper insulating layer 130. The first upper insulating layer 130 may cover the upper sidewall of the first through-via 170.

The first upper insulating layer 130 may include a first insulating layer 131 and a second insulating layer 132. The first insulating layer 131 may be disposed on the upper surface 110u of the first semiconductor substrate 110 and cover the upper surface of the first semiconductor substrate 110. The first insulating layer 131 may include a multi-layer or a single layer. The first insulating layer 131 may include a silicon-based insulating material.

The second insulating layer 132 may be disposed on the first insulating layer 131. The second insulating layer 132 may include a different material from the first insulating layer 131. For example, the second insulating layer 132 may include a silicon-based insulating material. In another example, the second insulating layer 132 may include an insulating polymer, such as polyimide. The upper surface of the second insulating layer 132 may correspond to the upper surface of the first semiconductor chip 100.

The first upper pad 160 may be disposed on the upper surface of the first semiconductor substrate 110. The first upper pad 160 may be provided on the first through-via 170 and electrically connected to the first through-via 170. In this specification, the level of a component may represent the vertical level thereof. The first upper pad 160 may be provided within the first upper insulating layer 130. The side surface and a portion of the lower surface of the first upper pad 160 may be covered by the first upper insulating layer 130. The upper surface of the first upper pad 160 may not be covered by the first upper insulating layer 130. The first upper pad 160 may include a metal, such as copper. The upper surface of the first semiconductor chip 100 may include the upper surface of the first upper insulating layer 130 and the upper surface of the first upper pad 160.

The first semiconductor chip 100 may have a recessed portion 190. The recessed portion 190 may be provided in the upper surface 100u of the dummy region DR of the first semiconductor substrate 110. The recessed portion 190 may not be provided in the chip region CR of the first semiconductor chip 100. The recessed portion 190 may be provided in a side wall or outer wall 100c of the first semiconductor chip 100. For example, the recessed portion 190 may be recessed inward from the outer wall 100c of the first semiconductor chip 100.

As shown in FIG. 1A, the outer wall 100c of the first semiconductor chip 100 may include a first outer wall 110a, a second outer wall 110b, a third outer wall, and a fourth outer wall. The second outer wall 110b may be adjacent to the first outer wall 110a. The third outer wall may be opposite to the first outer wall 110a and adjacent to the second outer wall 110b. The fourth outer wall may be opposite to the second outer wall 110b and adjacent to the first outer wall 110a and the third outer wall. The recessed portion 190 may include a first recessed portion 1901, a second recessed portion 1902, a third recessed portion 1903, and a fourth recessed portion 1904, as shown in FIG. 1A. The first recessed portion 1901 may be provided in the first outer wall 110a of the first semiconductor chip 100. The second recessed portion 1902 may be provided in the second outer wall 110b of the first semiconductor chip 100. The second recessed portion 1902 may be connected to the first recessed portion 1901. The third recessed portion 1903 may be provided in the third outer wall of the first semiconductor chip 100. The third recessed portion 1903 may be connected to the second recessed portion 1902. The fourth recessed portion 1904 may be provided in the fourth outer wall of the first semiconductor chip 100. The fourth recessed portion 1904 may be connected to the first recessed portion 1901 and the third recessed portion 1903.

As shown in FIG. 1B and FIG. 1C, the recessed portion 190 may be provided within the first upper insulating layer 130 and in the upper surface 130u of the first upper insulating layer 130. For example, the recessed portion 190 may be recessed into the first upper insulating layer 130 from the upper surface 130u of the first upper insulating layer 130. The recessed portion 190 may pass through the second insulating layer 132. The recessed portion 190 may further pass through at least a portion of the first insulating layer 131, but the embodiment is not limited thereto.

An inner surface 191 of the recessed portion 190 may be connected to the upper surface 100u of the first semiconductor chip 100 and the outer wall 100c of the first semiconductor chip 100. As shown in FIG. 1C, the inner surface 191 of the recessed portion 190 may have a bottom surface 191b and a sidewall 191c. The bottom surface 191b of the recessed portion 190 may be at a level lower than the upper surface 130u of the second insulating layer 132 and higher than the upper surface 110u of the first semiconductor substrate 110. For example, the bottom surface 191b of the recessed portion 190 may be provided within the first insulating layer 131, but the embodiment is not limited thereto. The sidewall 191c of the recessed portion 190 may include an inclined sidewall. The sidewall 191c of the recessed portion 190 may extend in a direction inclined relative to the upper surface 130u of the first upper insulating layer 130. For example, the angle between the sidewall 191c of the recessed portion 190 and the upper surface 130u of the first upper insulating layer 130 may be an obtuse angle.

The inner surface 191 of the recessed portion 190 may be relatively rough. The surface roughness of the inner surface 191 of the recessed portion 190 may be greater than the surface roughness of the upper surface 103u of the second insulating layer 132. The surface roughness of the inner surface 191 of the recessed portion 190 may be greater than the surface roughness of the outer wall 100c of the first semiconductor chip 100. The outer wall 100c of the first semiconductor chip 100 may include a side wall or outer wall 130c of the first upper insulating layer 130, the outer wall 110c of the first semiconductor substrate 110, and the side wall or outer wall 121c of the first lower insulating layer 121. In other words, the surface roughness of the inner surface 191 of the recessed portion 190 may be greater than the surface roughness of a side wall or outer wall 400c of the molding layer 400, the surface roughness of the outer wall 130c of the first upper insulating layer 130, the surface roughness of the outer wall 110c of the first semiconductor substrate 110, and the surface roughness of the outer wall 121c of the first lower insulating layer 121. The outer wall 130c of the first upper insulating layer 130 may include the outer wall of the first insulating layer 131.

The bottom surface 191b and the sidewall 191c of the recessed portion 190 may be rough. Specifically, the surface roughness of the bottom surface 191b of the recessed portion 190 and the surface roughness of the sidewall 191c of the recessed portion 190 may each be greater than the surface roughness of the upper surface 130u of the second insulating layer 132, the surface roughness of the outer wall 400c of the molding layer 400, the surface roughness of the outer wall 130c of the first upper insulating layer 130, the surface roughness of the outer wall 110c of the first semiconductor substrate 110, and the surface roughness of the outer wall 121c of the first lower insulating layer 121.

A depth D of the recessed portion 190 may be about 1 μm to about 10 μm. The depth D of the recessed portion 190 may represent the maximum depth of the recessed portion 190. A width W of the recessed portion 190 may be about 1 μm to about 20 μm. The width W of the recessed portion 190 may represent the maximum width of the recessed portion 190.

In FIG. 1A, the molding layer 400 is shown in transparency in order to show the shapes of the first insulating layer 131 and the second insulating layer 132 in plan view. The molding layer 400 may be provided on the upper surface 100u of the first semiconductor chip 100 and extend into the recessed portion 190. With reference to FIGS. 1B and 1C, the molding layer 400 may cover the inner surface 191 of the recessed portion 190. The molding layer 400 may include a first portion 409. The first portion 409 of the molding layer 400 may include a vertical protrusion. The first portion 409 of the molding layer 400 may be provided within the recessed portion 190 and cover the inner surface 191 of the recessed portion 190. For example, the first portion 409 of the molding layer 400 may be in direct physical contact with the inner surface 191 of the recessed portion 190. The depth of the first portion 409 of the molding layer 400 may be substantially equal to the depth D of the recessed portion 190. The width of the first portion 409 of the molding layer 400 may be substantially equal to the width W of the recessed portion 190. The outer wall 400c of the molding layer 400 may include the outer wall of the first portion 409 of the molding layer 400. The outer wall 400c of the molding layer 400, the outer wall 130c of the first upper insulating layer 130, the outer wall 110c of the first semiconductor substrate 110, and the outer wall of the first lower insulating layer 121 may be exposed to the outside. The outer wall 400c of the molding layer 400 may be vertically aligned with the outer wall 130c of the first upper insulating layer 130, the outer wall 110c of the first semiconductor substrate 110, and the outer wall 121c (FIG. 1D) of the first lower insulating layer 121. The molding layer 400 is described in more detail below.

Unlike that shown in the diagram, the upper surface 110u of the first semiconductor substrate 110 may correspond to the frontside surface, and the lower surface of the first semiconductor substrate 110 may correspond to the backside surface. In this case, the first integrated circuits 115 and the first wiring pattern 123 may be arranged on the upper surface of the first semiconductor substrate 110.

As shown in FIG. 1B, the second semiconductor chips 200 may be provided on the first semiconductor chip 100. For example, the second semiconductor chips 200 may be arranged on the chip region CR of the first semiconductor substrate 110. Each of the second semiconductor chips 200 may include a second semiconductor substrate 210, a second integrated circuit, a second lower insulating layer 221, a second lower pad 250, a second wiring pattern 223, a second through-via 270, a second upper pad 260, and a second upper insulating layer 230. Unless otherwise stated, the materials and electrical connection relationships of the second semiconductor substrate 210, the second integrated circuit, the second lower insulating layer 221, the second lower pad 250, the second wiring pattern 223, and the second through-via 270 may be substantially the same as the materials and electrical connection relationships of the first semiconductor substrate 110, the first integrated circuits 115, the first lower insulating layer 121, the first lower pad 150, the first wiring pattern 123, and the first through-via 170.

The second semiconductor substrate 210 may represent a second substrate. The second integrated circuits may be provided on the lower surface of the second semiconductor substrate 210. The lower surface of the second semiconductor substrate 210 may correspond to the frontside surface. The second integrated circuits may include different types of circuits from the first integrated circuits 115 (FIG. 1C). The second integrated circuits may include memory circuits. The second semiconductor substrate 210 may include a semiconductor material.

The second lower insulating layer 221 is provided on the lower surface of the second semiconductor substrate 210 and may cover the second integrated circuit. The second lower insulating layer 221 may be a multilayer. The second lower insulating layer 221 may include a silicon-based insulating material. The second wiring pattern 223 may be provided within the second lower insulating layer 221. The second wiring pattern 223 may include a metal.

The second lower pad 250 may be provided on the lower surface of the second semiconductor chip 200. For example, the second lower pad 250 may be disposed on the lower surface of the second lower insulating layer 221. The lower surface of the second semiconductor chip 200 may include the lower surface of the second lower pad 250 and the lower surface of the second lower insulating layer 221. The second lower pad 250 may be electrically connected to the second integrated circuit and/or the second through-via 270 via the second wiring pattern 223. The second lower pad 250 may include, for example, copper.

The second through-via 270 may be provided within the second semiconductor substrate 210 and pass through the second semiconductor substrate 210. The second through-via 270 may be electrically connected to the second wiring pattern 223. The second through-via 270 may include a metal.

The second upper insulating layer 230 may be disposed on the upper surface of the second semiconductor substrate 210. The upper surface of the second semiconductor substrate 210 may correspond to the backside surface. The second upper insulating layer 230 may be a multilayer. For example, the second upper insulating layer 230 may include a silicon-based insulating material.

The second upper pad 260 may be provided on the second through-via 270 and electrically connected to the second through-via 270. The second upper pad 260 may be located within the second upper insulating layer 230. The upper surface of the second upper pad 260 may not be covered by the second upper insulating layer 230. For example, the second upper pad 260 may include a metal, such as copper.

The uppermost second semiconductor chip 200 may include the second semiconductor substrate 210, the second integrated circuit, the second lower insulating layer 221, the second lower pad 250, and the second wiring pattern 223, but may not include the second through-via 270, the second upper pad 260, and the second upper insulating layer 230. The thickness of the second semiconductor substrate 210 of the uppermost second semiconductor chip 200 may be greater than the thickness of the second semiconductor substrate 210 of each of the other second semiconductor chips 200. The uppermost second semiconductor chip 200 may be referred to as a third semiconductor chip.

The semiconductor package 10 may further include a first bump 510. The first bump 510 is provided between the first semiconductor chip 100 and a second semiconductor chip 200 located at the bottom (hereinafter, referred to as a lowermost second semiconductor chip 200) and may be electrically connected to the first semiconductor chip 100 and the lowermost second semiconductor chip 200. For example, the first bump 510 is provided between the first upper pad 160 and the second lower pad 250 of the lowermost second semiconductor chip 200 and may be electrically connected to the first upper pad 160 and the second lower pad 250 of the lowermost second semiconductor chip 200. The first bump 510 may include a first solder ball, and the first solder ball may include a solder material. The first bump 510 may further include a first conductive pillar. In this case, the first conductive pillar may be provided between the first solder ball and the second lower pad 250 of the lowermost second semiconductor chip 200. The first conductive pillar may include a metal, such as copper.

The semiconductor package 10 may further include second bumps 520. The second bumps 520 may be provided between the second semiconductor chips 200 and electrically connected to the second semiconductor chips 200. Each of the second bumps 520 may be located between the second upper pad 260 and the second lower pad 250 facing each other and electrically connected to the second upper pad 260 and the second lower pad 250 facing each other. Each of the second bumps 520 may include a second solder ball, and the second solder ball may include a solder material. Each of the second bumps 520 may further include a second conductive pillar. In this case, the second conductive pillar may be provided between the second solder ball and the second lower pad 250. The second conductive pillar may include a metal, such as copper.

The molding layer 400 may be disposed on the upper surface of the first semiconductor chip 100 and cover the sidewalls of the second semiconductor chips 200. The upper surface of the molding layer 400 may expose the upper surface of the uppermost second semiconductor chip 200. For example, the upper surface of the molding layer 400 may be at substantially the same level as the upper surface of the uppermost second semiconductor chip 200. Unlike the above, the molding layer 400 may further cover the upper surface of the uppermost second semiconductor chip 200. The molding layer 400 may include an insulating polymer, such as an epoxy-based molding compound (EMC).

The semiconductor package 10 may further include a first insulating film 410. The first insulating film 410 is provided between the first semiconductor chip 100 and the lowermost second semiconductor chip 200 and may cover the sidewalls of the first bump 510. The first insulating film 410 may include a non-conductive film (NCF). The first insulating film 410 may include an insulating polymer different from the molding layer 400.

The semiconductor package 10 may further include a second insulating film 420. The second insulating film 420 is provided between the second semiconductor chips 200 and may cover the sidewalls of the second bumps 520. The second insulating film 420 may include an NCF. The second insulating film 420 may include an insulating polymer different from the molding layer 400.

FIG. 1E is a diagram illustrating a recessed portion according to embodiments and corresponds to an enlarged view of region II of FIG. 1B. Descriptions already given above are omitted.

Referring to FIG. 1E together with FIG. 1B, an inner surface 191 of a recessed portion 190 may include an inclined sidewall 191cc. For example, the inclined sidewall 191cc of the recessed portion 190 may connect the upper surface 130u of the first upper insulating layer 130 to the outer wall 130c of the first upper insulating layer 130. The inclined sidewall 191cc of the recessed portion 190 may extend in a direction inclined relative to the upper surface 130u of the first upper insulating layer 130. The inner surface 191 of the recessed portion 190 may be rough. For example, the surface roughness of the inner surface 191 of the recessed portion 190 may be greater than the surface roughness of the upper surface 130u of the first upper insulating layer 130, the surface roughness of the outer wall 400c of the molding layer 400, the surface roughness of the outer wall 130c of the first upper insulating layer 130, the surface roughness of the outer wall 110c of the first semiconductor substrate 110, and the surface roughness of the outer wall of the first lower insulating layer 121 (FIG. 1B).

FIG. 1F is a diagram illustrating a recessed portion according to embodiments and corresponds to an enlarged view of region II of FIG. 1B.

Referring to FIG. 1F together with FIG. 1B, an inner surface 191 of a recessed portion 190 may include a bottom surface 191b and a sidewall 191c. The bottom surface 191b and the sidewall 191c of the recessed portion 190 may be rough. The bottom surface 191b and sidewall 191c of the recessed portion 190 may be substantially identical to those described in the embodiment of FIG. 1C. However, the sidewall 191c of the recessed portion 190 may be substantially perpendicular to the upper surface 130u of the first upper insulating layer 130.

FIG. 1G is a diagram illustrating a recessed portion according to embodiments and corresponds to an enlarged view of region II of FIG. 1B.

Referring to FIG. 1G, a recessed portion 190 is provided within a second insulating layer 132 and may not extend into a first insulating layer 131. For example, the lowermost surface of the recessed portion 190 may be provided within the second insulating layer 132. The lowermost surface of the recessed portion 190 is spaced apart from the first insulating layer 131 and may be at a higher level than the upper surface of the first insulating layer 131. The inner surface 191 of the recessed portion 190 may be rough.

FIG. 1H is a diagram illustrating a recessed portion according to embodiments and corresponds to an enlarged view of region II of FIG. 1B.

Referring to FIG. 1H, a recessed portion 190 may be provided within a second insulating layer 132 and a first insulating layer 131. The recessed portion 190 may expose the first semiconductor substrate 110. The recessed portion 190 may extend into the first semiconductor substrate 110. The lowermost surface of the recessed portion 190 may be provided within the first semiconductor substrate 110. The lowermost surface of the recessed portion 190 may be at a lower level than the upper surface 110u of the first semiconductor substrate 110. The inner surface 191 of the recessed portion 190 may be rough.

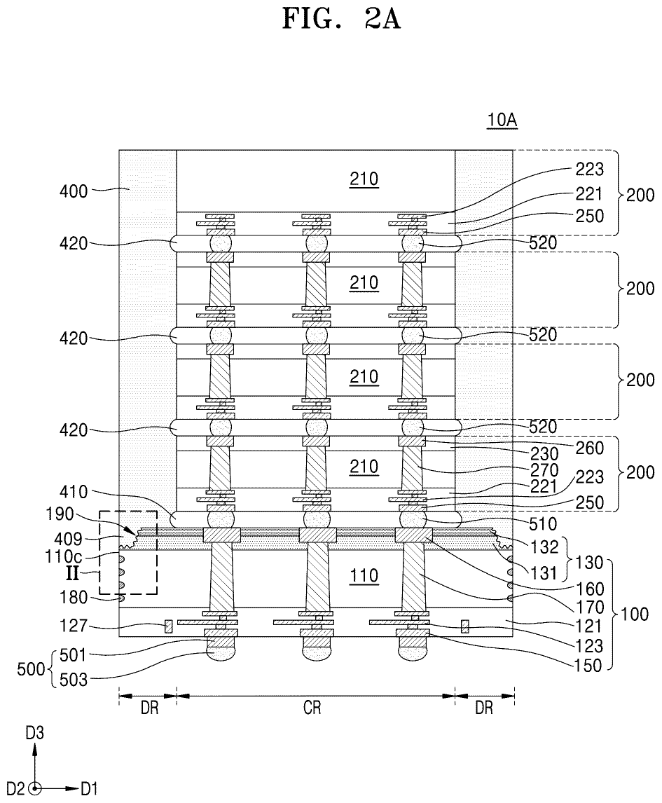

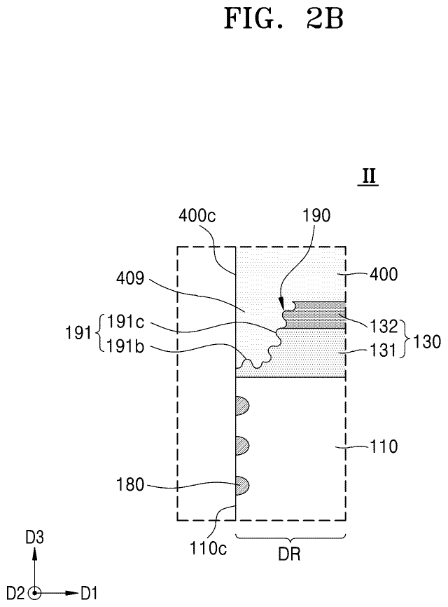

FIG. 2A is a diagram illustrating a semiconductor package according to embodiments and corresponds to a cross-section of the semiconductor package taken along line I-I′ of FIG. 1A. FIG. 2B is an enlarged view of region II of FIG. 2A.

Referring to FIGS. 2A and 2B together with FIG. 1A, a semiconductor package 10A may include a first semiconductor chip 100, second semiconductor chips 200, a molding layer 400, and a lower bump 500. A semiconductor package 10A may include a memory package, such as an HBM package. The semiconductor package 10A may include a chip stack package.

A first semiconductor chip 100 may include a first semiconductor substrate 110, a first lower pad 150, a first wiring pattern 123, a first through-via 170, a first upper insulating layer 130, and a first upper pad 160. The first semiconductor substrate 110 may include a crystalline semiconductor substrate. The first semiconductor substrate 110 may include an amorphous portion 180. The amorphous portion 180 may be provided in a dummy region DR of the first semiconductor substrate 110. The amorphous portion 180 may be provided in an outer wall 110c of the first semiconductor substrate 110. For example, the amorphous portion 180 may be exposed on the outer wall 110c of the first semiconductor substrate 110. The amorphous portion 180 may be any one of a plurality of amorphous portions 180. The amorphous portions 180 may be vertically spaced from each other within the first semiconductor substrate 110, but the embodiment is not limited thereto. Unlike the illustration in the diagram, the sizes of the amorphous portions 180 may be different from each other, but the embodiment is not limited thereto.

The first semiconductor chip 100 may have a recessed portion 190. The recessed portion 190 may be substantially the same as described in the examples of FIGS. 1A to 1C and FIGS. 1E to 1H.

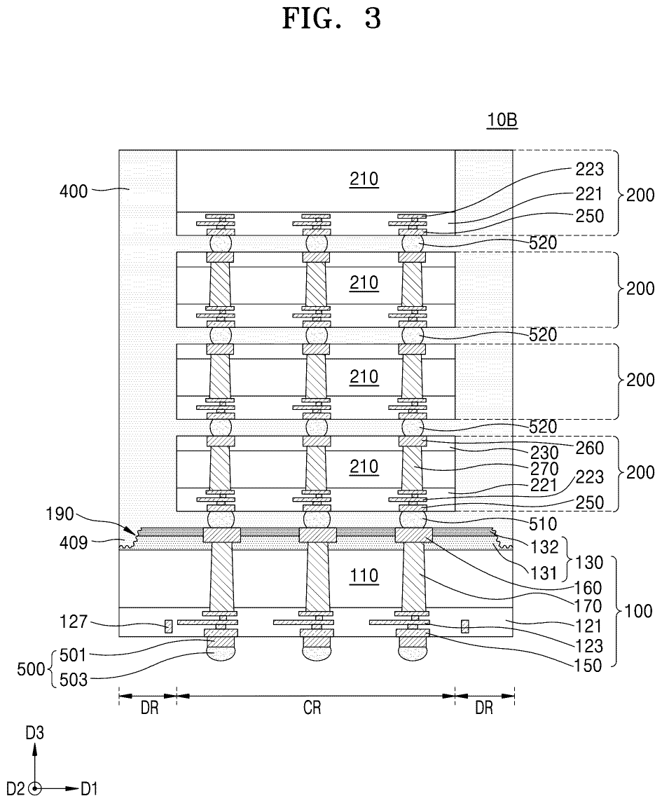

FIG. 3 is a diagram illustrating a semiconductor package according to embodiments and corresponds to a cross-section of the semiconductor package taken along line I-I′ of FIG. 1A.

Referring to FIG. 3, a semiconductor package 10B may include a first semiconductor chip 100, second semiconductor chips 200, a molding layer 400, a lower bump 500, a first bump 510, and second bumps 520. The semiconductor package 10B may include a chip stack package.

The molding layer 400 may have a molded underfill structure. For example, the molding layer 400 may be provided on the upper surface of the first semiconductor chip 100 and cover sidewalls of the second semiconductor chips 200. The molding layer 400 may extend into spaces between the second semiconductor chips 200 and seal the second bumps 520. The molding layer 400 may further extend into a space between the first semiconductor chip 100 and the lowermost second semiconductor chip 200 and seal the first bump 510. The semiconductor package 10B may not include the first insulating film 410 and the second insulating film 420 of FIG. 1B.

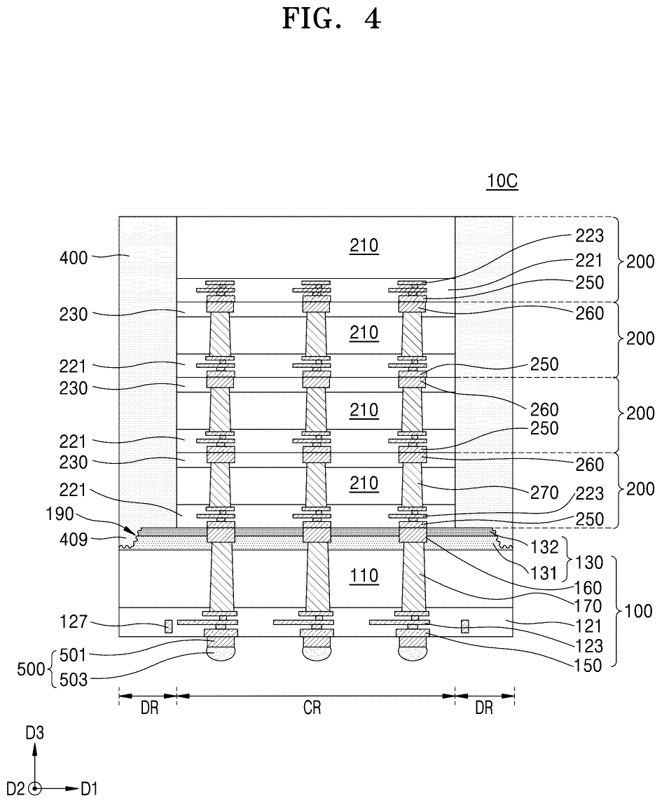

FIG. 4 is a diagram illustrating a semiconductor package according to embodiments and corresponds to a cross-section of the semiconductor package taken along line I-I′ of FIG. 1A.

Referring to FIG. 4, a semiconductor package 10C may include a first semiconductor chip 100, second semiconductor chips 200, a molding layer 400, and a lower bump 500. The semiconductor package 10C may include a chip stack package.

The lowermost second semiconductor chip 200 may be directly bonded to the first semiconductor chip 100. The semiconductor package 10C may not include the first bump 510 and the first insulating film 410 of FIG. 1B. The direct bonding may be formed by a hybrid bonding process. A second lower pad 250 of the lowermost second semiconductor chip 200 may be directly bonded to a first upper pad 160. For example, the second lower pad 250 of the lowermost second semiconductor chip 200 may be directly disposed on the first upper pad 160 and be in direct physical contact with the first upper pad 160. The second lower pad 250 of the lowermost second semiconductor chip 200 may include the same metal as the first upper pad 160 (e.g., copper). The interface between the second lower pad 250 and the first upper pad 160 of the lowermost second semiconductor chip 200 may not be distinguished, but the embodiment is not limited thereto.

A second lower insulating layer 221 of the lowermost second semiconductor chip 200 may be directly bonded to a first upper insulating layer 130. For example, a chemical bond may be formed between the second lower insulating layer 221 of the lowermost second semiconductor chip 200 and the first upper insulating layer 130. Accordingly, the second lower insulating layer 221 of the lowermost second semiconductor chip 200 may be firmly bonded to the first upper insulating layer 130. The second lower insulating layer 221 of the lowermost second semiconductor chip 200 may include the same insulating material as the first upper insulating layer 130, but the embodiment is not limited thereto. For example, the interface between the second lower insulating layer 221 of the lowermost second semiconductor chip 200 and the first upper insulating layer 130 may not be distinguished.

The second semiconductor chips 200 may be directly bonded to each other. For example, a second upper pad 260 and a second lower pad 250 facing each other may be in direct contact with each other and directly bonded to each other. The interface between the second upper pad 260 and the second lower pad 250 that are directly bonded to each other may not be distinguished. The interface between the second upper pad 260 and the second lower pad 250 that are directly bonded to each other may be a virtual interface. The second lower pad 250 may include the same metal as the second upper pad 260 directly bonded thereto (e.g., copper).

A second lower insulating layer 221 may be directly bonded to the second upper insulating layer 230 facing the second lower insulating layer 221. For example, the second lower insulating layer 221 may be in direct contact with the second upper insulating layer 230 facing the second lower insulating layer 221. A chemical bond may be formed between the second lower insulating layer 221 and the second upper insulating layer 230 that are directly bonded to each other. Accordingly, a strong bond may be formed between the second lower insulating layer 221 and the second upper insulating layer 230 that are directly bonded to each other. The second lower insulating layer 221 may include the same material as the second upper insulating layer 230 directly bonded to the second lower insulating layer 221, but the embodiment is not limited thereto. For example, the interface between the second lower insulating layer 221 and the second upper insulating layer 230 that are directly bonded to each other may not be distinguished.

Embodiments may be combined in various ways. For example, at least two of the embodiment of FIGS. 1A to 1D, the embodiment of FIG. 1E, the embodiment of FIG. 1F, the embodiment of FIG. 1G, the embodiment of FIG. 1H, the embodiment of FIGS. 2A and 2B, the embodiment of FIG. 3, and the embodiment of FIG. 4 may be combined with each other. For example, the semiconductor package 10B of FIG. 3 or the semiconductor package 10C of FIG. 4 may include the first semiconductor chip 100 having the recessed portion 190 as described in the embodiment of FIG. 1E, the embodiment of FIG. 1F, the embodiment of FIG. 1G, or the embodiment of FIG. 1H. In another example, the first semiconductor chip 100 of the semiconductor package 10B of FIG. 3 or the semiconductor package 10C of FIG. 4 may include the first semiconductor substrate 110 including the amorphous portions 180 as described in the examples of FIGS. 2A and 2B.

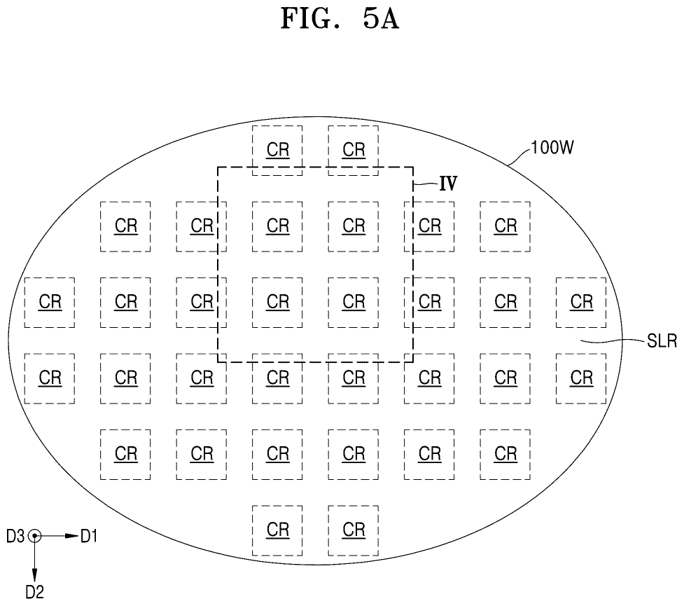

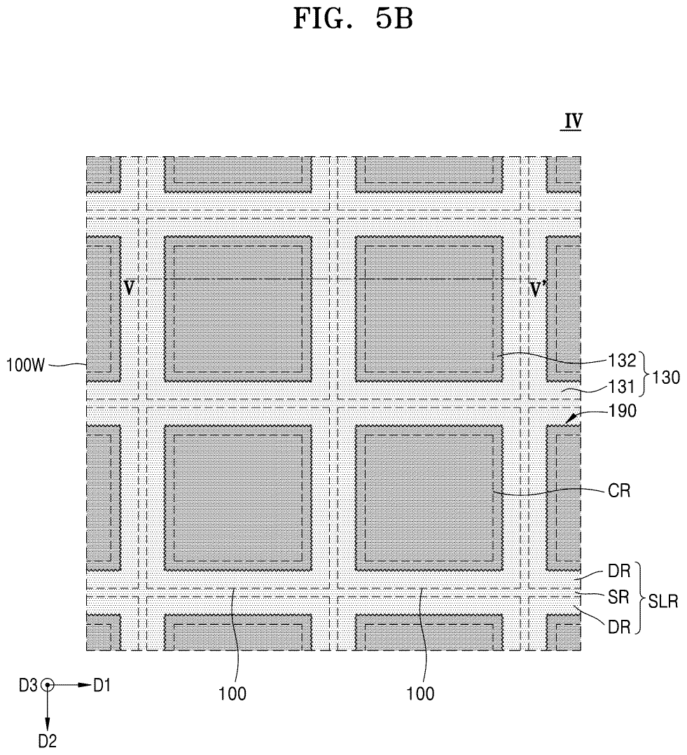

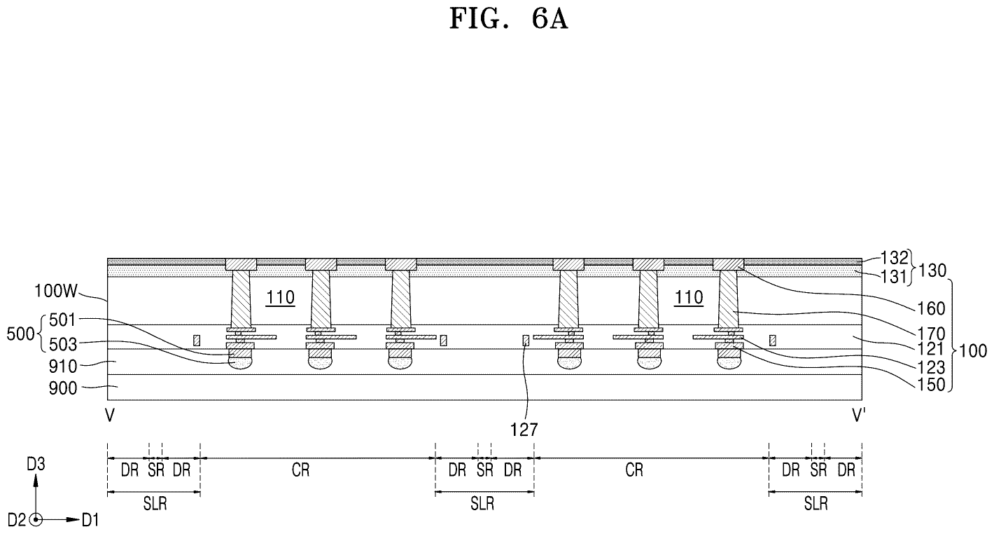

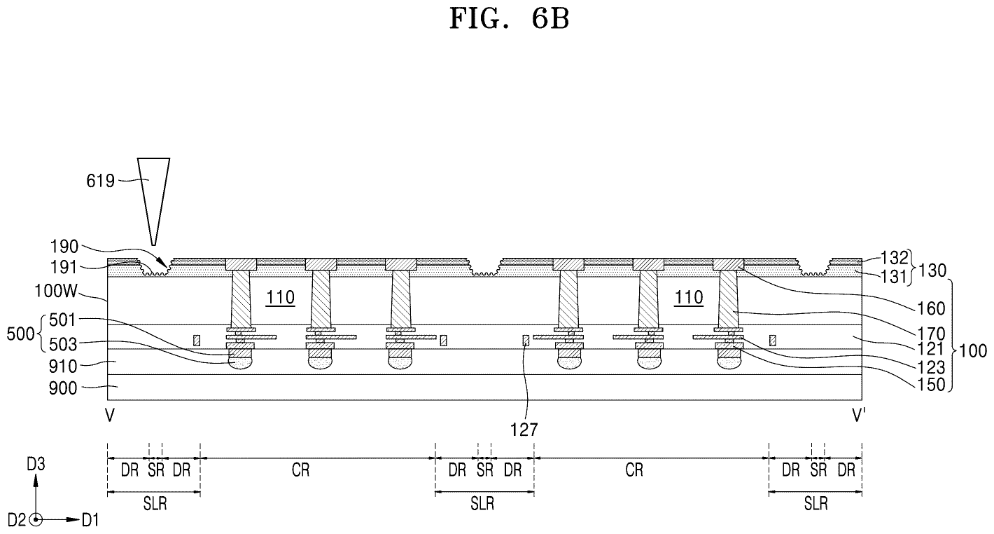

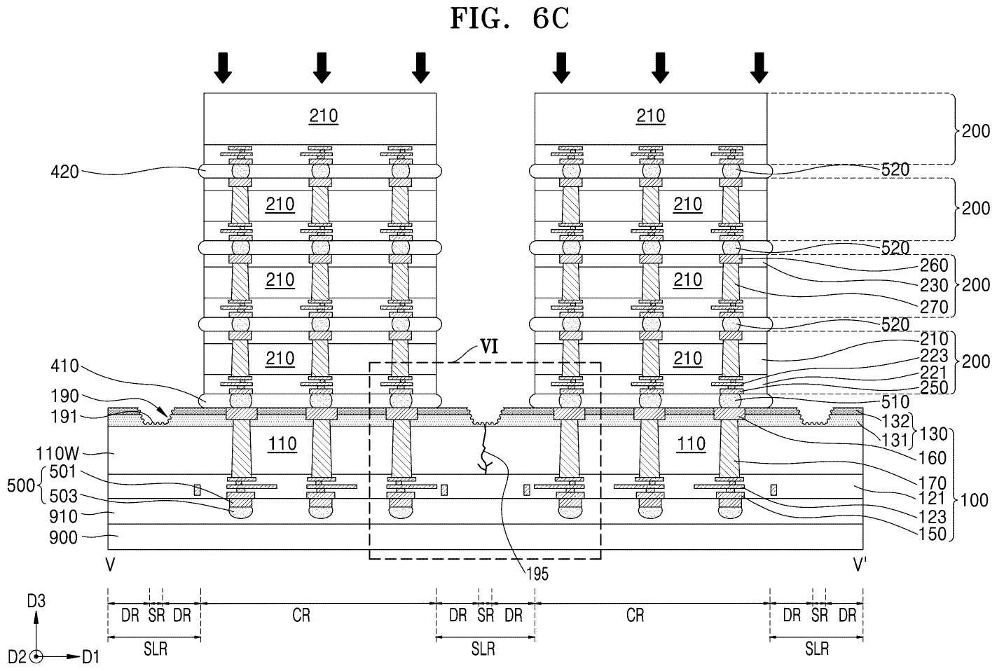

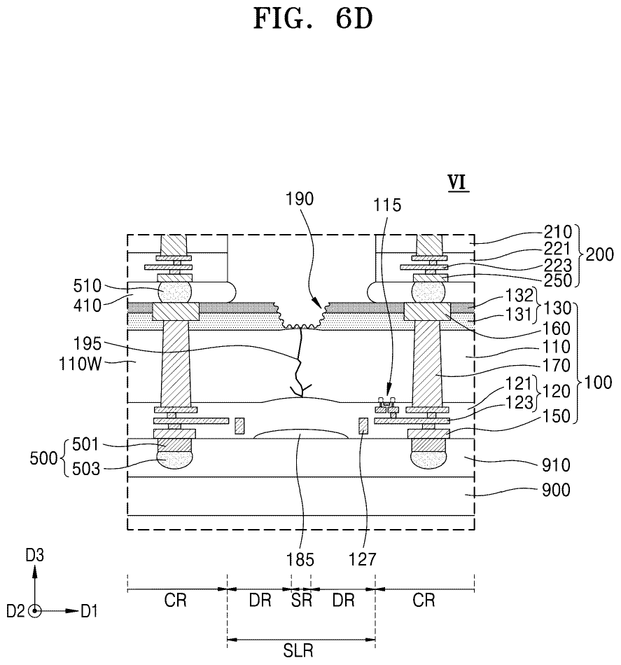

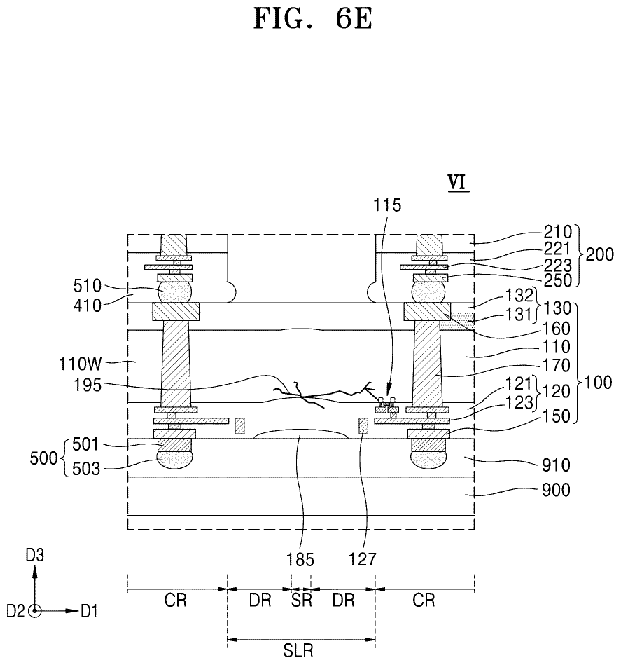

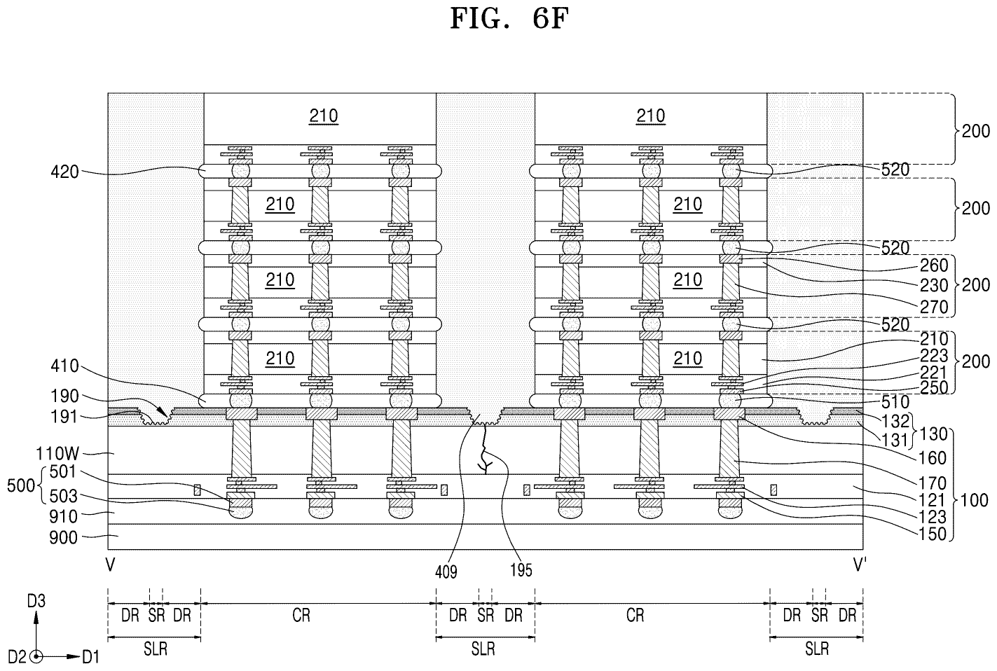

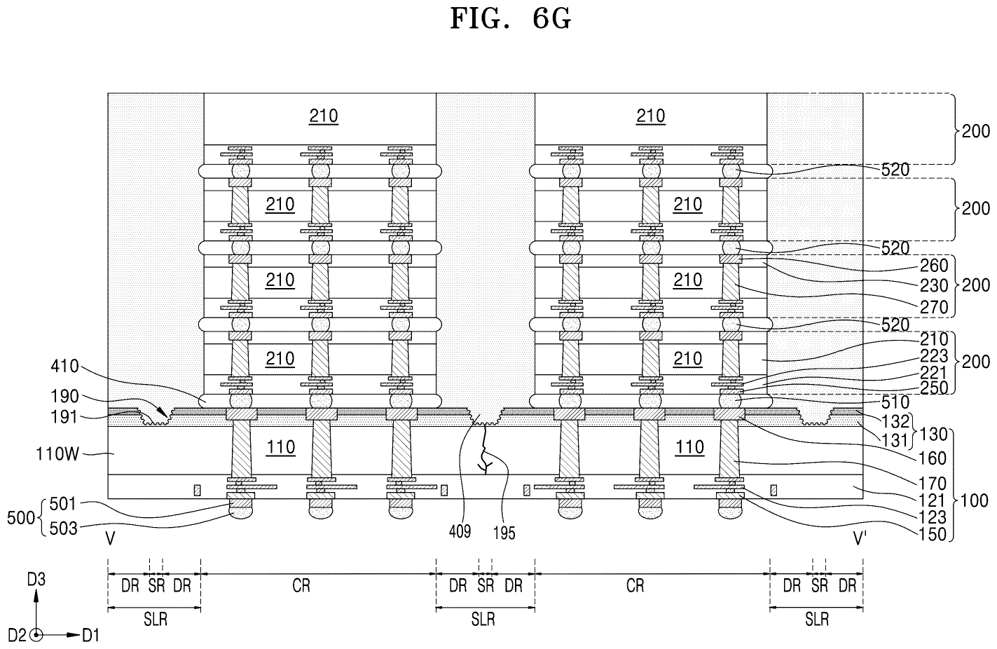

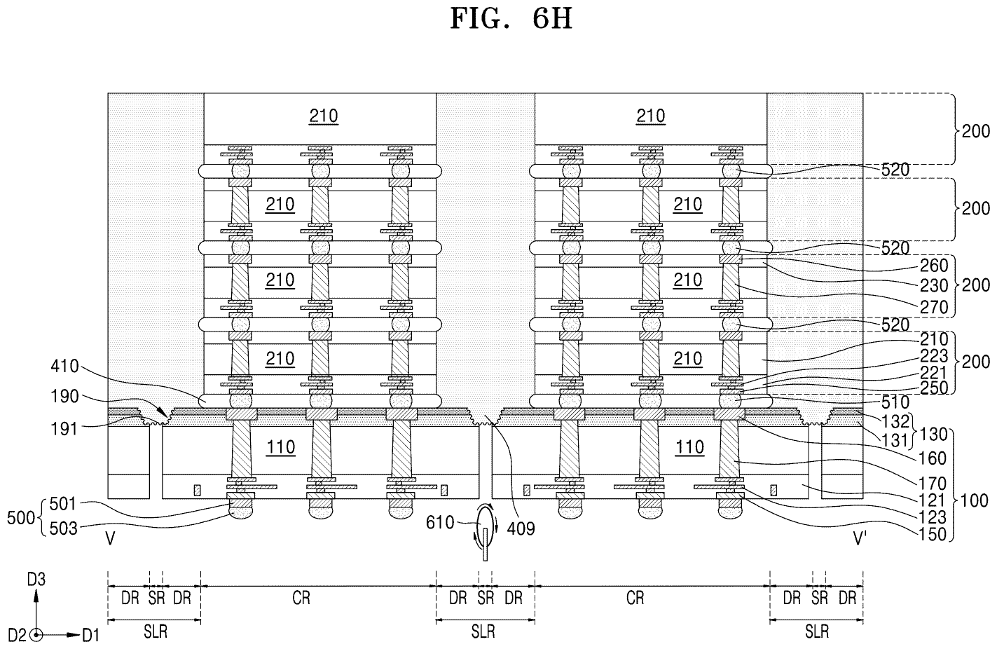

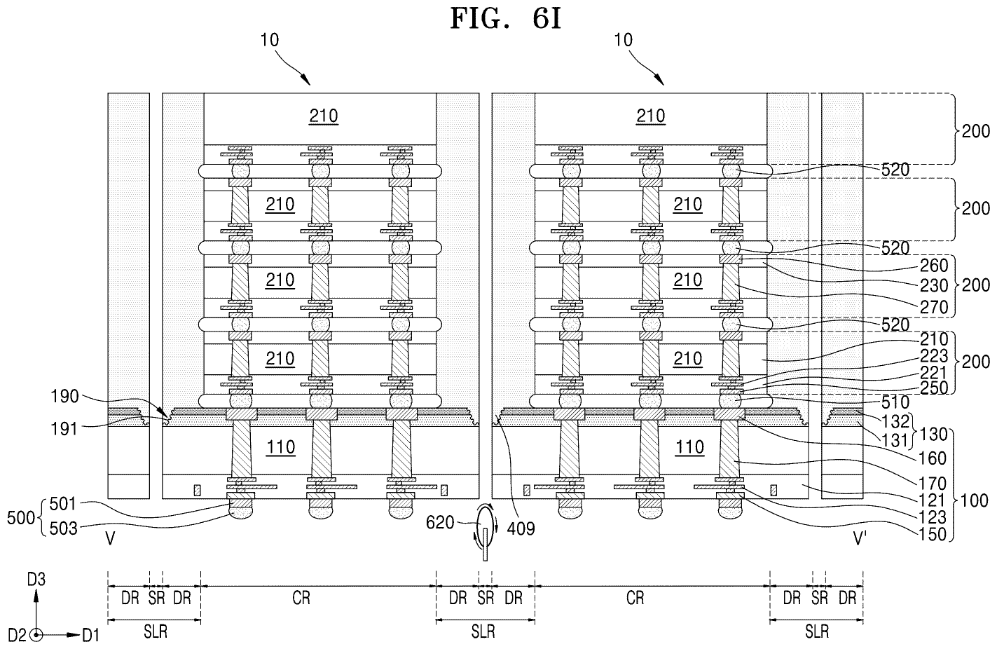

FIG. 5A is a cross-sectional view illustrating a semiconductor wafer according to embodiments. FIG. 5B is an enlarged view of region IV of FIG. 5A. FIGS. 6A to 6I are diagrams illustrating a manufacturing process of a semiconductor package, according to embodiments. FIGS. 6A, 6B, 6C, 6F, 6G, 6H, and 6I correspond to cross-sections of the semiconductor wafer taken along line V-V′ of FIG. 5B. FIG. 6C is an enlarged view of region VI of FIG. 6B. Hereinafter, descriptions already given above are omitted.

Referring to FIGS. 5A and 5B, a semiconductor wafer 100W may be provided. The semiconductor wafer 100W includes a semiconductor substrate wafer 110W (FIG. 6B) including a plurality or array of sections each corresponding to respective one of a plurality of first semiconductor substrates 110. The semiconductor wafer 100W may have a plurality of chip regions CR and a scribe lane region SLR in a plan view. The plurality of chip regions CR may be arranged in rows parallel to a first direction D1 and in columns parallel to a second direction D2. Each of the plurality of chip regions CR may include a region used as the first semiconductor substrate 110 of the first semiconductor chip 100 described with reference to FIG. 1B. The scribe lane region SLR of the semiconductor wafer 100W may be positioned between the plurality of chip regions CR. The plurality of chip regions CR of the semiconductor wafer 100W may be spaced apart from each other by the scribe lane region SLR.

The scribe lane region SLR of the semiconductor wafer 100W may be located between the chip regions CR. The scribe lane region SLR of the semiconductor wafer 100W may have a grid pattern in a plan view. For example, the scribe lane region SLR of the semiconductor wafer 100W may include first regions extending parallel to the first direction D1 and second regions extending parallel to the second direction D2 in a plan view. The second regions of the scribe lane region SLR may be connected to the first regions. The chip regions CR may be surrounded by the scribe lane region SLR. The scribe lane region SLR may include a virtual region. The scribe lane region SLR may include a sawing region SR and a dummy region DR. The sawing region SR of the scribe lane region SLR may include a region that is removed in a first sawing process described below with reference to FIG. 6H. The sawing region SR may have a grid pattern in a plan view. The sawing region SR and the dummy region DR may be virtual regions. The dummy region DR may be provided between the sawing region SR and the chip regions CR. Since the dummy region DR is provided, damage to components of the chip regions CR may be prevented during a sawing process. The above components may include at least one of the first integrated circuits 115, the first wiring pattern 123, the first lower pad 150, the first upper pad 160, and the first through-via 170, which are described above with reference to FIGS. 1B and 1C.

Referring to FIGS. 5B and 6A, the semiconductor wafer 100W may include a plurality of first semiconductor substrates 110, each forming a part of the semiconductor substrate wafer 110W. The first semiconductor substrates 110 may be arranged side by side and connected to each other. Each of the first semiconductor substrates 110 may have one chip region CR and one dummy region DR. The sawing region SR of the semiconductor wafer 100W may be provided between the first semiconductor substrates 110. Each of the first semiconductor substrates 110 may correspond to the first semiconductor substrate 110 of the respective first semiconductor chip 100. In the following description, the chip regions CR of the semiconductor wafer 100W and the chip region CR of the first semiconductor substrate 110 are used without distinction. For example, each of the chip regions CR of the semiconductor wafer 100W may be interpreted as indicating the chip region CR of the first semiconductor substrate 110. Similarly, the dummy region DR of the semiconductor wafer 100W and the dummy region DR of the first semiconductor substrate 110 are used without distinction. For example, the dummy region DR of the semiconductor wafer 100W may be interpreted as indicating the dummy region DR of the first semiconductor substrate 110.

The first semiconductor chips 100 may be formed on the semiconductor wafer 100W. The first semiconductor chips 100 may be formed at a wafer level. For example, a first lower insulating layer 121, a first wiring pattern 123, a first lower pad 150, a guide ring 127, and a plurality of lower bumps 500 may be formed, at a wafer level, on the lower surface of each of the portions of the semiconductor wafer 100W corresponding to the first semiconductor substrates 110.

The first semiconductor substrates 110 may be arranged on the carrier substrate 900 such that the lower bumps 500 face the carrier substrate 900. A glue layer 910 is provided between the carrier substrate 900 and the first lower insulating layer 121, and thus, the first lower insulating layer 121 may be attached to the carrier substrate 900. The glue layer 910 may cover sidewalls of the lower bumps 500. Subsequently, a backside process is performed on the upper surface of the first semiconductor substrate wafer 110W, and thus, the first semiconductor substrates 110 may be thinned. The backside process may include a grinding process or a chemical mechanical polishing process. A first insulating layer 131, a first upper pad 160, and a second insulating layer 132 may be formed on the upper surfaces of the portions of the semiconductor wafer 110W corresponding to the first semiconductor substrates 110. Accordingly, the first semiconductor chips 100 may be manufactured. Each first semiconductor chip 100 may include the first semiconductor substrate 110, the first lower pad 150, the first wiring pattern 123, the first lower insulating layer 121, the first through-via 170, a first upper insulating layer 130, and the first upper pad 160. The first upper insulating layer 130 may include the first insulating layer 131 and the second insulating layer 132. The first semiconductor chip 100 may further include the guide ring 127.

Referring to FIG. 6B, laser may be emitted onto the upper surface of the first semiconductor chip 100 to form a recessed portion 190 in the upper surface of the first semiconductor chip 100. The laser irradiation may be performed using a first laser device 619. The first laser device 619 may be disposed above the upper surface of the first semiconductor chip 100. The recessed portion 190 may be formed in the upper surface of the first upper insulating layer 130 and within the first upper insulating layer 130. The forming of the recessed portion 190 may include partially removing the first upper insulating layer 130 by laser irradiation. The laser beam may be emitted along the sawing region SR of the semiconductor wafer 100W. Accordingly, the recessed portion 190 as shown in FIGS. 5B and 6B may be formed along the scribe lane region SLR of the semiconductor wafer 100W. Specifically, the recessed portion 190 may be formed in the sawing region SR of the semiconductor wafer 100W. At least a portion of the recessed portion 190 may extend into the dummy region DR of the semiconductor wafer 100W. For example, the recessed portion 190 may have a grid pattern in a plan view, as shown in FIG. 5B. For example, the recessed portion 190 may include a first recess region and a second recess region. The first recess region may have a major axis parallel to the first direction D1. The second recess region may have a major axis parallel to the second direction D2. The second recess region may be connected to the first recess region.

Referring to FIGS. 6C and 6D, a plurality of second semiconductor chips 200 may be mounted on the first semiconductor chip 100. For example, the plurality of second semiconductor chips 200 may be stacked on the chip region CR of the first semiconductor substrate 110. A first bump 510 and a first insulating film 410 may be formed between the first semiconductor chip 100 and the lowermost second semiconductor chip 200. A plurality of second bumps 520 and a plurality of second insulating films 420 may be formed between the second semiconductor chips 200. The mounting of the second semiconductor chips 200 may be performed, for example, by a thermocompression bonding process. During the thermocompression bonding process, a void 185 may be formed between the first lower insulating layer 121 and the glue layer 910 in the semiconductor wafer 100W, as shown in FIG. 6D. The void 185 may overlap the scribe lane region SLR of the semiconductor wafer 100W.

During the thermocompression bonding process, pressure may be applied to the second semiconductor chips 200 in the mounting process of the second semiconductor chips 200. The pressure may be delivered to the chip region CR of the semiconductor wafer 100W. The second semiconductor chips 200 may not be provided on the scribe lane region SLR of the semiconductor wafer 100W. No pressure may be applied to the scribe lane region SLR of the semiconductor wafer 100W. During the thermocompression bonding process, heat may be applied between the second semiconductor chips 200 and the first semiconductor chip 100. The glue layer 910 may have a different coefficient of thermal expansion (CTE) from the components of the first semiconductor chip 100 and the components of the second semiconductor chip 200. The components of the first semiconductor chip 100 may have different CTEs. The components of the second semiconductor chip 200 may have different CTEs. The components of the first semiconductor chip 100 may include the first semiconductor substrate 110, the first lower pad 150, the first wiring pattern 123, the first through-via 170, the first upper insulating layer 130, and the first upper pad 160. The components of the second semiconductor chip 200 may include a second semiconductor substrate 210, a second lower pad 250, a second lower insulating layer 221, a second wiring pattern 223, a second through-via 270, a second upper insulating layer 230, and a second upper pad 260. The scribe lane region SLR of the semiconductor wafer 100W may be separated from the glue layer 910 due to the difference in the pressure and CTE. Accordingly, the void 185 may be formed.

A crack 195 may occur in the semiconductor wafer 100W due to the void 185. The crack may be formed in and extend partially or fully through the semiconductor substrate wafer 110W. In another example, the crack 195 may be formed between the semiconductor wafer 100W and the first lower insulating layer 121. In another example, the crack 195 may be formed within the first lower insulating layer 121. The crack 195 may overlap the scribe lane region SLR of the semiconductor wafer 100W in a plan view. As the number of stacked second semiconductor chips 200 increases, the occurrence of cracks 195 may increase. In diagrams other than FIGS. 6D and 6E, the void 185 is omitted for simplicity.

FIG. 6E is a diagram illustrating the propagation of a crack when the recessed portion is omitted.

Referring to FIG. 6E, cracks 195 may be formed within the scribe lane region SLR of the semiconductor wafer 100W. The cracks 195 may propagate in random directions. For example, the cracks 195 may propagate into the chip region CR of the semiconductor wafer 100W. In this case, damage to the first integrated circuits 115, the first wiring pattern 123, the first lower pad 150, or the first through-via 170 may occur due to the cracks 195. Accordingly, a defect in the first semiconductor chip 100 may occur. Losses may occur during the manufacturing process of semiconductor packages.

Referring back to FIGS. 6C and 6D, each recessed portion 190 may be provided in a scribe lane region SLR of the semiconductor wafer 100W and within the first upper insulating layer 130. The recessed portion 190 may guide the propagation of the cracks 195. For example, even if a crack 195 occurs, the crack 195 may propagate toward the recessed portion 190. According to embodiments, the depth and width of the recessed portion 190 may be adjusted, and accordingly, the recessed portion 190 may guide the crack 195 so that the crack 195 propagates in a desired direction. For example, the cracks 195 may propagate vertically within the scribe lane region SLR of the semiconductor wafer 100W and may not propagate to the chip regions CR of the semiconductor wafer 100W. Accordingly, damage to components within the chip regions CR of the semiconductor wafer 100W may be prevented. The manufacturing process yield of semiconductor packages may be improved. The components within the chip regions CR of the semiconductor wafer 100W may include at least one of first integrated circuits 115, the first wiring pattern 123, the first lower pad 150, the first upper pad 160, and the first through-via 170.

According to some embodiments, since the recessed portion 190 is provided, damage to the components within the chip regions CR of the semiconductor wafer 100W may be prevented even if the number of stacked second semiconductor chips 200 increases. Accordingly, even if a large number of second semiconductor chips 200 are stacked, the semiconductor packages may be manufactured with a high yield.

According to some embodiments, the guide ring 127 may be further provided within the first semiconductor substrate 110. The guide ring 127 may further prevent damage to the first integrated circuits 115, the first wiring pattern 123, and the first lower pad 150. For example, the guide ring 127 may protect the first integrated circuits 115, the first wiring pattern 123, or the first lower pad 150 from the cracks 195.

Referring to FIG. 6F, a molding layer 400 may be formed on the upper surface of the first semiconductor chip 100 so as to cover sidewalls of the second semiconductor chips 200. The formation of the molding layer 400 may be performed at a wafer level. The molding layer 400 may formed on the upper surface of the first upper insulating layer 130 and extend into the recessed portion 190. The molding layer 400 may fill the recessed portion 190. For example, the molding layer 400 may be in direct contact with an inner surface 191 of the recessed portion 190. Accordingly, the molding layer 400 may include a first portion 409 within the recessed portion 190.

Referring to FIG. 6G, the carrier substrate 900 and the glue layer 910 are removed from the semiconductor wafer 100W or semiconductor chips 100, and thus, the lower bumps 500 and the lower surface of each first semiconductor chip 100 may be exposed. For example, the lower surface of the first lower insulating layer 121 may be exposed.

Sequentially referring to FIGS. 6G and 6H, the first semiconductor chip or chips 100 may be cut by the first sawing process using a first blade 610. For example, the first lower insulating layer 121, the semiconductor wafer 100W, and the first upper insulating layer 130 may be cut. Accordingly, a plurality of first semiconductor substrates 110 may be separated from each other.

In this manner, the first semiconductor chips 100 are separated from one another. For example, the plurality of first semiconductor substrates 110 may be spaced laterally from each other. The sawing region SR of the semiconductor wafer 100W may be removed by the first sawing process. A portion of the first lower insulating layer 121 and a portion of the first upper insulating layer 130 corresponding to the sawing region SR of the semiconductor wafer 100W may be removed by the first sawing process. The cracks 195 may be removed together with the sawing region SR of the semiconductor wafer 100W. The semiconductor wafer 100W may be more easily sawed by the cracks 195. Even if the cracks 195 are further formed within the dummy region DR of the semiconductor wafer 100W, since the dummy region DR of the semiconductor wafer 100W is provided between the sawing region SR and the chip regions CR, damage to components of the chip region CR of the semiconductor wafer 100W may be prevented during the sawing process. The dummy region DR of the semiconductor wafer 100W may not be removed in the first sawing process. Hereinafter, for simplicity of description, a single first semiconductor substrate 110 will be described.

As a result of the first sawing process, the outer wall 100c of the first semiconductor chip 100 may be exposed. For example, the outer wall 121C of the first lower insulating layer 121, the outer wall 110c of the first semiconductor substrate 110, and the outer wall 130c of the first upper insulating layer 130 may be exposed. Each of the outer wall 121c of the first lower insulating layer 121, the outer wall 110c of the first semiconductor substrate 110, and the outer wall 130c of the first upper insulating layer 130 may be a cut surface. Since the first lower insulating layer 121, the first semiconductor substrate 110, and the first upper insulating layer 130 are cut by a blade sawing process, the outer wall of the first lower insulating layer 121, the outer wall of the first semiconductor substrate 110, and the outer wall of the first upper insulating layer 130 may be smooth. For example, the surface roughness of the outer wall 121c of the first lower insulating layer 121, the surface roughness of the outer wall 110c of the first semiconductor substrate 110, and the surface roughness of the outer wall 130c of the first upper insulating layer 130 may be less than the surface roughness of the inner surface 191 of the recessed portion 190.

Referring to FIG. 6I, the molding layer 400 may be cut by a second sawing process using a second blade 620, and thus, respective, individual semiconductor packages 10 may be manufactured and separated from one another. The second blade 620 may be a different type of blade than the first blade 610 (FIG. 6H), but the embodiment is not limited thereto. A portion of the molding layer 400 corresponding to the sawing region SR of the semiconductor wafer 100W may be removed by the sawing of the second blade 620. As a result of the second sawing process, the outer wall 400c of the molding layer 400 may be exposed. The first portion 409 of the molding layer 400 may be sawed by the second sawing process. After the sawing process, the outer wall of the first portion 409 of the molding layer 400 may be exposed. The outer wall of the molding layer 400 may be a cut surface. Since the molding layer 400 is cut by a blade sawing process, the outer wall 400c of the molding layer 400 may be smooth. For example, the surface roughness of the outer wall 400c of the molding layer 400 may be less than the surface roughness of the inner surface 191 of the recessed portion 190.

The recessed portion 190 may be sawed by the first sawing process of FIG. 6H and the second sawing process of FIG. 6I. After completion of the first and second sawing processes, the depth D of the recessed portion 190 as shown in FIG. 1C may be about 1 μm to about 10 μm. The width W of the recessed portion 190 may be about 1 μm to about 20 μm. When the depth and width of the recessed portion 190 satisfy the above conditions, the recessed portion 190 may better guide the propagation of the cracks 195 as described in the examples of FIGS. 6C and 6D. In addition, handling of the semiconductor wafers 100W in FIG. 1C may be facilitated.

Each of the semiconductor packages 10 may be identical to the semiconductor package 10 described in the example of FIG. 1A. For example, each of the semiconductor packages 10 may include the first semiconductor chip 100, the second semiconductor chips 200, the molding layer 400, and the lower bumps 500.

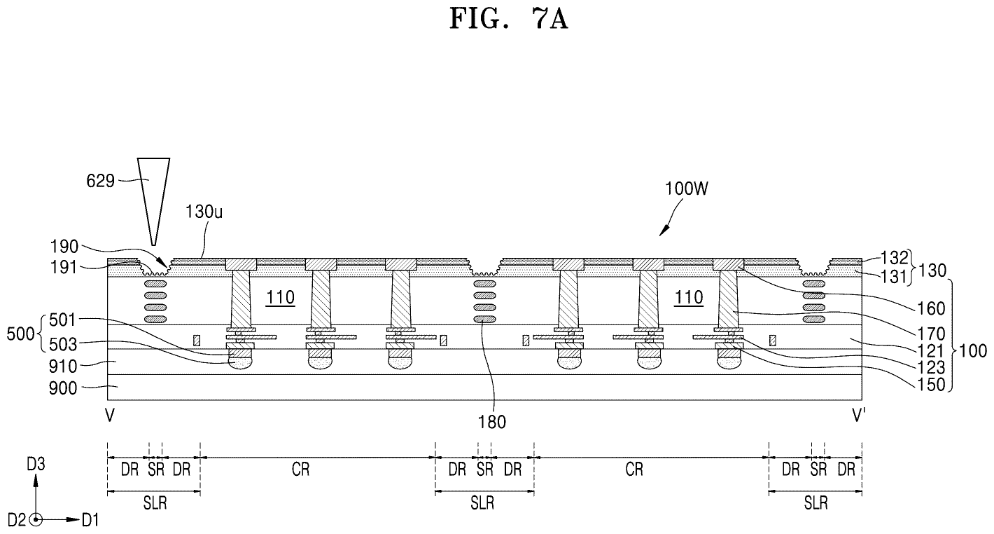

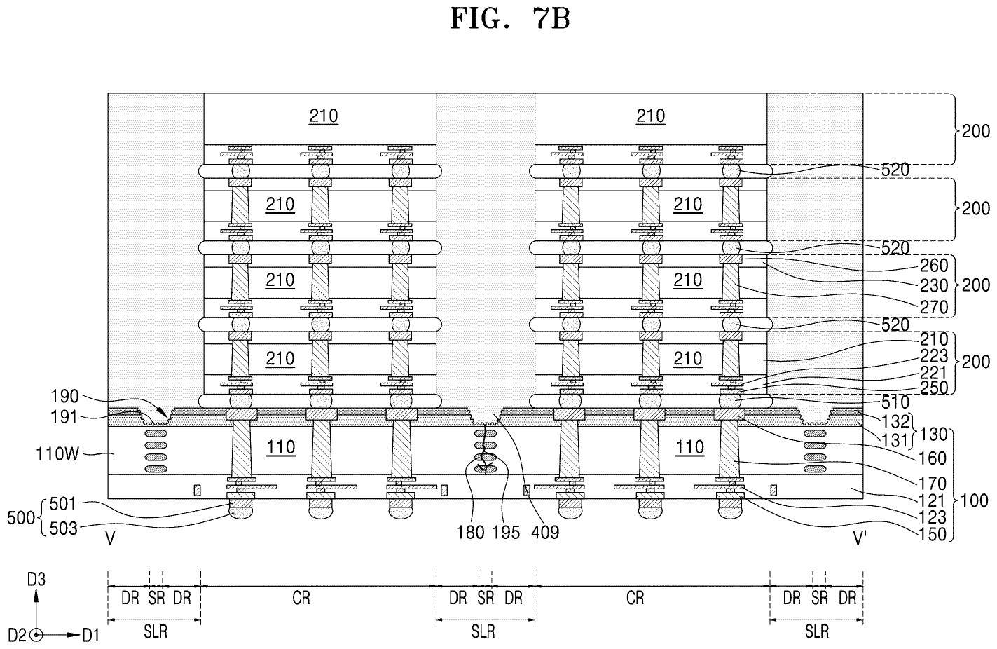

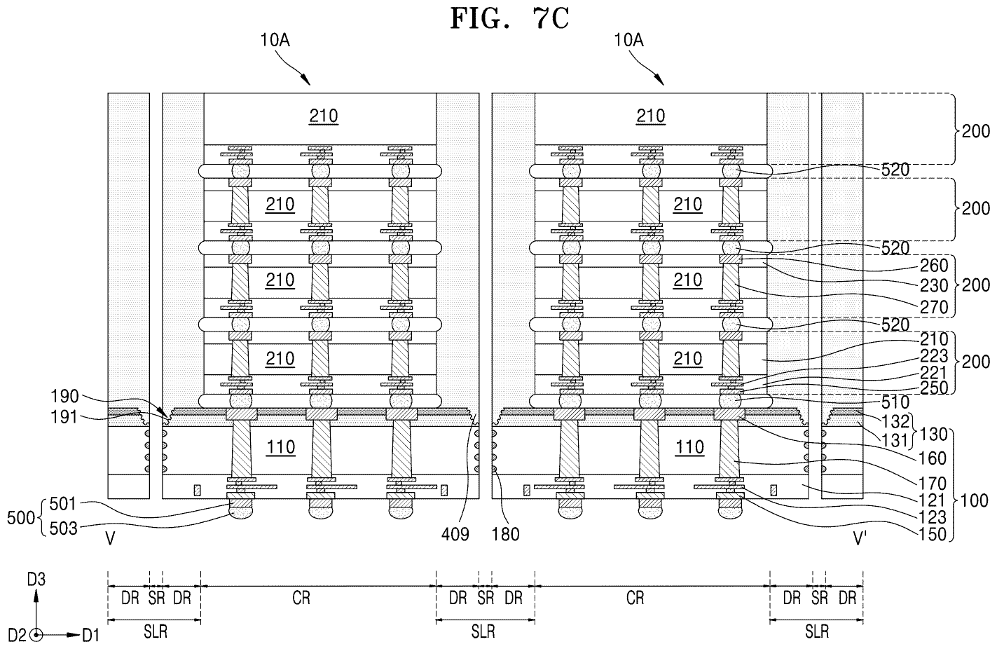

FIGS. 7A to 7C are diagrams illustrating a manufacturing process of a semiconductor package according to embodiments and correspond to cross-sections of the semiconductor wafer taken along line V-V′ of FIG. 5B. Hereinafter, when describing FIGS. 7A to 7C, FIG. 5B is referred to together.

Referring to FIG. 7A, a first semiconductor chip or chips 100 may be formed on a carrier substrate 900. The first semiconductor chip or chips 100 may be attached to the carrier substrate 900 by a glue layer 910. Each first semiconductor chip 100 may be formed by the same method as described in the example of FIG. 6A.

A laser beam may be emitted onto the first semiconductor chip 100 to form a recessed portion 190 and amorphous portions 180. The laser irradiation may be performed using a second laser device 629. The second laser device 629 may be disposed above the upper surface of the first semiconductor chip 100. The second laser device 629 may be different from the first laser device 619 of FIG. 6B. The recessed portion 190 may be formed in the upper surface 130u of a first upper insulating layer 130 and within the first upper insulating layer 130.

The laser beam may be emitted from the second laser device 629 into a semiconductor wafer 100W, and thus, the semiconductor wafer 100W may be locally heated. The crystal structures of the heated regions of the semiconductor wafer 100W may be changed. Accordingly, the amorphous portions 180 may be formed within the semiconductor wafer 100W. The laser beam may be emitted along the sawing region SR of the semiconductor wafer 100W. The amorphous portions 180 may be formed within the sawing region SR of the semiconductor wafer 100W. The amorphous portions 180 may vertically overlap the recessed portion 190. For example, the amorphous portions 180 may be formed at different depths within the semiconductor wafer 100W, but the embodiment is not limited thereto. The amorphous portions 180 may be vertically spaced apart from each other. The cross-sectional shapes and sizes of the amorphous portions 180 may be variously modified.

Referring to FIG. 7B, the second semiconductor chips 200 may be mounted on the first semiconductor chip 100. During mounting of the second semiconductor chips 200, cracks 195 may be formed within the scribe lane region SLR of the semiconductor wafer 100W.

According to some embodiments, the amorphous portions 180 may guide the propagation of cracks 195. For example, even if a crack 195 occurs, the crack 195 may propagate vertically along the amorphous portions 180. Since the amorphous portions 180 are vertically spaced apart from each other, the vertical propagation of the cracks 195 may be guided more easily. As described in FIGS. 6C and 6D, the recessed portion 190 may guide the propagation of the cracks 195. For example, the cracks 195 may propagate vertically to the recessed portion 190 along the amorphous portions 180. The propagation of the cracks 195 may be confined within the scribe lane region SLR of the semiconductor wafer 100W. The cracks 195 may not propagate to the chip regions CR of the semiconductor wafer 100W. Accordingly, damage to components within the chip regions CR of the semiconductor wafer 100W may be prevented. Therefore, the manufacturing process yield of semiconductor packages may be improved. The manufactured semiconductor packages may have improved reliability.

The molding layer 400 may be formed on the first semiconductor substrate 110 to fill the recessed portion 190. For example, the molding layer 400 may have a first portion 409. The first portion 409 of the molding layer 400 may be in direct contact with the inner surface 191 of the recessed portion 190. Subsequently, the carrier substrate 900 and the glue layer 910 are removed, and thus, the lower bumps 500 and the lower surface of the first semiconductor chip 100 may be exposed.

Referring to FIG. 7C, the first semiconductor chip 100 may be cut by a laser sawing process to manufacture a plurality of semiconductor packages 10A. The laser sawing process may include the first sawing process using the first blade 610 as described in the example of FIG. 6H and the second sawing process using the second blade 620 as described in the example of FIG. 6I. The first lower insulating layer 121, the semiconductor wafer 100W, and the first upper insulating layer 130 may be cut by the first sawing process. The sawing region SR of the first semiconductor wafer 100W, a portion of the first lower insulating layer 121, and a portion of the first upper insulating layer 130 may be removed. The above portion of the first lower insulating layer 121 and the above portion of the first upper insulating layer 130 may correspond to the sawing region SR of the semiconductor wafer 100W. The cracks 195 may be removed together with the sawing region SR of the semiconductor wafer 100W. Also, first portions of the amorphous portions 180 may be removed together with the sawing region SR of the semiconductor wafer 100W. The semiconductor wafer 100W can be cut more easily by the cracks 195 and the amorphous portions 180. For example, the cracks 195 and amorphous portions 180 may assist in cutting a semiconductor wafer 100W.

After the first sawing process is completed, the outer wall of the first semiconductor chip 100 may be exposed. Second portions of the amorphous portions 180 may remain on the outer wall of the first semiconductor chip 100. The second portions of the amorphous portions 180 may be exposed on the outer wall of the first semiconductor chip 100. The second portions of the amorphous portions 180 may be provided on the dummy region DR of the first semiconductor chip 100.

The molding layer 400 may be cut by the second sawing process. In this case, the first portion 409 of the molding layer 400 may be sawed, and thus, the outer wall of the first portion 409 of the molding layer 400 may be exposed. As a result of the second sawing process, a plurality of semiconductor packages 10A may be manufactured. Each of the plurality of semiconductor packages 10A may be identical to the semiconductor package 10A described in the example of FIG. 2A. Each of the semiconductor packages 10 may include the first semiconductor chip 100, the second semiconductor chips 200, the molding layer 400, and the lower bumps 500.

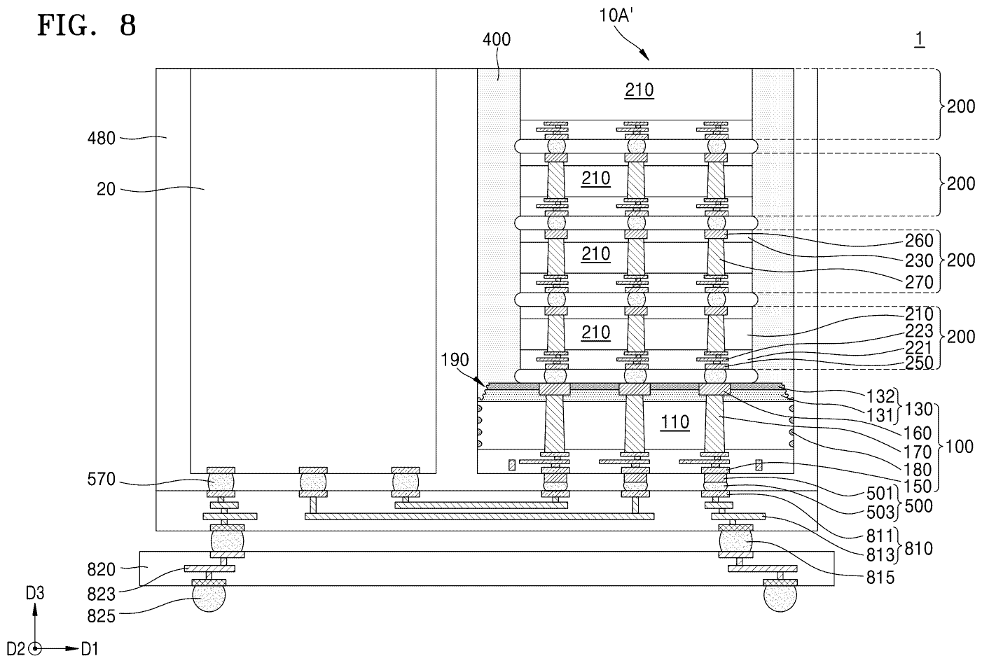

FIG. 8 is a cross-sectional view illustrating a semiconductor package 1 according to embodiments.

Referring to FIG. 8, the semiconductor package 1 may include solder balls 825, a package substrate 820, interposer solder balls 815, an interposer substrate 810, a semiconductor element 20, and a chip stack package 10A′.

For example, a printed circuit board may be used as the package substrate 820. The package substrate 820 may include substrate wires 823. The substrate wires 823 may be provided within the package substrate 820. The expression in which a component is electrically connected to the package substrate 820 may indicate that the component is electrically connected to at least one of the substrate wires 823. The substrate wires 823 may include metals, such as copper, aluminum, tungsten, and titanium.

The solder balls 825 may be provided on the lower surface of the package substrate 820 and electrically connected to the substrate wires 823. External electrical signals may be transmitted to the solder balls 825. The solder balls 825 may include solder materials.

The interposer substrate 810 may be provided above the package substrate 820. The interposer substrate 810 may include upper interposer pads 811 and interposer wires 813. The upper interposer pads 811 may be arranged on the upper surface of the interposer substrate 810. The upper interposer pads 811 may include metals. The interposer wires 813 may be provided within the interposer substrate 810 and electrically connected to the upper interposer pads 811. The expression in which a component is electrically connected to the interposer substrate 810 may indicate that the component is electrically connected to at least one of the interposer wires 813. The interposer wires 813 may include metals, such as copper, aluminum, tungsten, and titanium.

The interposer solder balls 815 may be arranged between the package substrate 820 and the interposer substrate 810 and electrically connected to the package substrate 820 and the interposer substrate 810. The pitch of the interposer solder balls 815 may be less than the pitch of the solder balls 825. The interposer solder balls 815 may include solder materials.

The chip stack package 10A′ may be disposed on the upper surface of the interposer substrate 810. The semiconductor package 10A described in the example of FIG. 2A may be used as the chip stack package 10A′. For example, the chip stack package 10A′ may include a first semiconductor chip 100, second semiconductor chips 200, a molding layer 400, and lower bumps 500. Unlike the above, the semiconductor package 10 of FIG. 1A, the semiconductor package 10B of FIG. 3, or the semiconductor package 10C of FIG. 4 may be used as the chip stack package 10A′.

The lower bumps 500 may be disposed on the upper interposer pads 811 and electrically connected to the upper interposer pads 811. For example, the lower bumps 500 may be respectively bonded to the upper surfaces of the upper interposer pads 811. The pitch of the lower bumps 500 may be less than the pitch of the interposer solder balls 815.

The semiconductor element 20 may be provided on the interposer substrate 810 and spaced laterally from the chip stack package 10A′. The semiconductor element 20 may include a graphics processing unit (GPU) or a central processing unit (CPU). The semiconductor element 20 may be a different type of semiconductor chip from the first semiconductor chip 100 and the second semiconductor chips 200. The semiconductor element 20 may perform a different function from the first semiconductor chip 100 and the second semiconductor chips 200. The semiconductor element 20 may include integrated circuits and chip pads. The integrated circuits may be provided within the semiconductor element 20. The chip pads may be provided on the lower surface of the semiconductor element 20 and electrically connected to the integrated circuits of the semiconductor element 20.

Conductive bumps 570 may be arranged between the interposer substrate 810 and the semiconductor element 20. For example, the conductive bumps 570 may be electrically connected to the chip pads of the semiconductor element 20 and corresponding upper interposer pads 811. The conductive bumps 570 may include solder materials. The pitch of the conductive bumps 570 may be less than the pitch of the interposer solder balls 815. The semiconductor element 20 may be electrically connected to the chip stack package 10A′ via the interposer substrate 810. The semiconductor element 20 may be electrically connected to the package substrate 820 and the solder balls 825 via the interposer substrate 810.

A molding pattern 480 may be disposed on the upper surface of the interposer substrate 810 to cover the sidewalls of the chip stack package 10A′ and the sidewalls of the semiconductor element 20. For example, the molding pattern 480 may cover the outer walls of the first semiconductor chip 100 and the outer walls of the molding layer 400. The molding pattern 480 may be in direct physical contact with the outer walls of the amorphous portions 180 of the first semiconductor substrate 110. The molding pattern 480 may include a polymer, such as an epoxy molding compound. The molding pattern 480 may have insulating characteristics.

Unlike that shown in the diagram, the semiconductor package 1 may include two or more chip stack packages 10′. In this case, the semiconductor element 20 may be located between the chip stack packages 10′.

According to the inventive concept, a recessed portion may be provided in a scribe lane region of a semiconductor wafer and within a first upper insulating layer. In a manufacturing process of a semiconductor package, even if a crack is formed within the scribe lane region of the semiconductor wafer, the recessed portion may guide the crack so that the crack propagates locally within the scribe lane region of the semiconductor wafer. The crack may not propagate into a chip region of the semiconductor wafer. Accordingly, damage to components within the chip region of the semiconductor wafer may be prevented. The manufacturing process yield of semiconductor packages may be improved. The manufactured semiconductor packages may have improved reliability.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first semiconductor chip having a chip region and a dummy region surrounding the chip region in a plan view;
a second semiconductor chip on an upper surface of the chip region of the first semiconductor chip; and
a molding layer configured to cover the second semiconductor chip on the first semiconductor chip,
wherein the first semiconductor chip has a recessed portion in an outer wall of the first semiconductor chip and an upper surface of the dummy region of the first semiconductor chip, and
wherein a surface roughness of an inner surface of the recessed portion of the first semiconductor chip is greater than a surface roughness of an outer wall of the molding layer.

2. The semiconductor package of claim 1, wherein:
the first semiconductor chip comprises a semiconductor substrate,
the semiconductor substrate comprises a crystalline semiconductor material, and
the semiconductor substrate further comprises an amorphous portion exposed on an outer wall of the semiconductor substrate.

3. The semiconductor package of claim 1, wherein:
the molding layer comprises a vertical protrusion, the vertical protrusion being provided within the recessed portion of the first semiconductor chip, and
the outer wall of the molding layer comprises an outer wall of the vertical protrusion of the molding layer.

4. The semiconductor package of claim 1, wherein:
the recessed portion of the first semiconductor chip comprises:
a first recessed portion in a first outer wall of the first semiconductor chip; and
a second recessed portion in a second outer wall of the first semiconductor chip,
the second outer wall of the first semiconductor chip is adjacent to the first outer wall of the first semiconductor chip, and
the second recessed portion of the first semiconductor chip is connected to the first recessed portion of the first semiconductor chip.

5. The semiconductor package of claim 1, wherein the inner surface of the recessed portion of the first semiconductor chip is connected to an upper surface of the first semiconductor chip and the outer wall of the first semiconductor chip.

6. The semiconductor package of claim 1, wherein the surface roughness of the inner surface of the recessed portion of the first semiconductor chip is greater than a surface roughness of the outer wall of the first semiconductor chip.

7. The semiconductor package of claim 1, wherein:
the first semiconductor chip comprises:
a semiconductor substrate; and
an upper insulating layer on an upper surface of the semiconductor substrate, and
the recessed portion of the first semiconductor chip is provided within the upper insulating layer and in an outer wall of the upper insulating layer.

8. The semiconductor package of claim 1, wherein:
the inner surface of the recessed portion of the first semiconductor chip comprises a bottom surface and a sidewall,
a surface roughness of the bottom surface of the recessed portion is greater than the surface roughness of the outer wall of the molding layer, and
a surface roughness of the sidewall of the recessed portion is greater than the surface roughness of the outer wall of the molding layer.

9. The semiconductor package of claim 1, wherein:
a depth of the recessed portion of the first semiconductor chip is about 1 μm to about 10 μm, and
a width of the recessed portion of the first semiconductor chip is about 1 μm to about 20 μm.

10. The semiconductor package of claim 1, further comprising:
an interposer substrate;
bumps between the interposer substrate and the first semiconductor chip; and
a semiconductor element disposed on an upper surface of the interposer substrate and laterally spaced apart from the first semiconductor chip,
wherein the first semiconductor chip is electrically connected to the semiconductor element via the interposer substrate.

11. A semiconductor package comprising:
a first semiconductor chip;
a second semiconductor chip on an upper surface of the first semiconductor chip; and
a molding layer configured to cover a sidewall of the second semiconductor chip on the upper surface of the first semiconductor chip,
wherein the first semiconductor chip comprises:
a semiconductor substrate; and
an upper insulating layer provided on the semiconductor substrate and having a recessed portion,
wherein the recessed portion of the upper insulating layer is provided in an outer wall and an upper surface of the upper insulating layer, and
wherein a surface roughness of an inner surface of the recessed portion of the upper insulating layer is greater than a surface roughness of an outer wall of the semiconductor substrate.

12. The semiconductor package of claim 11, wherein the molding layer comprises a first portion, and the first portion of the molding layer is provided within the recessed portion of the upper insulating layer to cover the inner surface of the recessed portion of the upper insulating layer.

13. The semiconductor package of claim 12, wherein the surface roughness of the inner surface of the recessed portion of the upper insulating layer is greater than a surface roughness of an outer wall of the first portion of the molding layer.

14. The semiconductor package of claim 11, wherein:
the semiconductor substrate comprises a crystalline semiconductor substrate, and
the crystalline semiconductor substrate further comprises an amorphous portion exposed on an outer wall of the crystalline semiconductor substrate.

15. The semiconductor package of claim 11, wherein:
the upper insulating layer comprises a first insulating layer and a second insulating layer on the first insulating layer, and
a lowermost surface of the recessed portion of the upper insulating layer is provided within the second insulating layer.

16. The semiconductor package of claim 11, wherein:
the upper insulating layer comprises a first insulating layer and a second insulating layer on the first insulating layer, and
a lowermost surface of the recessed portion of the upper insulating layer is provided within the first insulating layer.

17. The semiconductor package of claim 11, wherein:
the inner surface of the recessed portion of the upper insulating layer comprises an inclined sidewall, and
the inclined sidewall of the recessed portion of the upper insulating layer is connected to the upper surface of the first semiconductor chip and an outer wall of the first semiconductor chip.

18. A semiconductor package comprising:
a first semiconductor chip comprising a first semiconductor substrate, a first lower insulating layer on a lower surface of the first semiconductor substrate, a first lower pad on a lower surface of the first lower insulating layer, a first through-via within the first semiconductor substrate, a first upper pad electrically connected to the first through-via, and a first upper insulating layer on an upper surface of the first semiconductor substrate;
a plurality of second semiconductor chips stacked on an upper surface of the first semiconductor chip, each of the plurality of second semiconductor chips comprising a second semiconductor substrate, a second lower insulating layer, a second lower pad, a second through-via, a second upper insulating layer, and a second upper pad;
a molding layer disposed on the upper surface of the first semiconductor chip and configured to cover sidewalls of the plurality of second semiconductor chips; and
a lower bump provided on a lower surface of the first semiconductor chip and electrically connected to the first lower pad,
wherein:
the first semiconductor chip has a recessed portion in an outer wall of the first semiconductor chip and the upper surface of the first semiconductor chip,
a surface roughness of an inner surface of the recessed portion of the first semiconductor chip is greater than a surface roughness of an outer wall of the molding layer and a surface roughness of an outer wall of the first semiconductor substrate, and
the molding layer extends into the recessed portion of the first semiconductor chip and covers the inner surface of the recessed portion of the first semiconductor chip.

19. The semiconductor package of claim 18, wherein the recessed portion of the first semiconductor chip comprises:
a first recessed portion in a first outer wall of the first semiconductor chip;
a second recessed portion in a second outer wall of the first semiconductor chip;
a third recessed portion in a third outer wall of the first semiconductor chip; and
a fourth recessed portion in a fourth outer wall of the first semiconductor chip,
wherein the second outer wall of the first semiconductor chip is adjacent to the first outer wall of the first semiconductor chip,
the third outer wall of the first semiconductor chip is adjacent to the second outer wall of the first semiconductor chip and opposite to the first outer wall of the first semiconductor chip,
the second recessed portion of the first semiconductor chip is connected to the first recessed portion and the third recessed portion of the first semiconductor chip, and
the third recessed portion of the first semiconductor chip is connected to the second recessed portion and the fourth recessed portion of the first semiconductor chip.

20. The semiconductor package of claim 18, wherein a thickness of the first semiconductor chip is about 7 μm to about 60 μm.
